(19) United States
(12) Patent Application Publication
(10) Pub. No.: US 2026/0045946 A1
(43) Pub. Date: Feb. 12, 2026

(54) SIGNAL TRANSMISSION DEVICE, ELECTRONIC DEVICE AND VEHICLE

(71) Applicant: ROHM CO., LTD., Kyoto-shi (JP)

(72) Inventor: Koki MISHIMA, Kyoto-shi (JP)

(21) Appl. No.: 19/290,554

(22) Filed: Aug. 5, 2025

(30) Foreign Application Priority Data
Aug. 7, 2024 (JP) 2024-130688

(51) Int. Cl. H03K 17/687

(52) U.S. Cl. CPC H03K 17/6871; H03K 2217/0063

(57) ABSTRACT

A signal transmission device includes a transmission circuit which outputs a control signal, a reception circuit and an insulating circuit. The reception circuit receives an input of an external signal. The reception circuit drives a drive target switch based on the control signal in a state where the external signal is at a first logic level at which the voltage of the external signal is equal to or lower than a first threshold voltage, and drives and controls the drive target switch based on the external signal regardless of the control signal in a state where the external signal is at a second logic level at which the voltage of the external signal is higher than the first threshold voltage.

### CROSS REFERENCE TO RELATED APPLICATIONS

The present invention claims priority under 35 U.S.C. § 119 to Patent Application No. 2024-130688 filed in Japan on Aug. 7, 2024, the entire contents of which are hereby incorporated by reference.

### TECHNICAL FIELD

The present disclosure relates to a signal transmission device, an electronic device and a vehicle.

### BACKGROUND ART

Conventionally, a signal transmission device which transmits a pulse signal while insulating an area between an input and an output is used in various applications (such as a power supply device and a motor driving device).

As an example of a conventional technology related to the above description, Patent Document 1 can be mentioned.

### SUMMARY OF INVENTION

A signal transmission device according to an aspect of the present disclosure includes a transmission circuit, a reception circuit and an insulating circuit. The transmission circuit is configured to output, according to an input signal, a control signal that is pulse-driven. The reception circuit is configured to drive a drive target switch according to the control signal. The insulating circuit is configured to transmit the control signal while insulating an area between the transmission circuit and the reception circuit. The reception circuit receives an input of an external signal different from the input signal. The reception circuit drives the drive target switch based on the control signal in a state where the external signal is at a first logic level at which a voltage of the external signal is equal to or lower than a first threshold voltage, and drives and controls the drive target switch based on the external signal regardless of the control signal in a state where the external signal is at a second logic level at which the voltage of the external signal is higher than the first threshold voltage.

An electronic device according to an aspect of the present disclosure includes the signal transmission device of the configuration described above, a control circuit, an external signal generation circuit and the drive target switch. The control circuit is configured to generate the input signal. The external signal generation circuit is configured to generate the external signal.

A vehicle according to an aspect of the present disclosure includes: the electronic device of the configuration described above.

### BRIEF DESCRIPTION OF DRAWINGS

FIG. 1 is a diagram illustrating the basic configuration of a signal transmission device.

FIG. 2 is a diagram illustrating the basic structure of a transformer chip.

FIG. 3 is a perspective view of a semiconductor device used as a two-channel transformer chip.

FIG. 4 is a plan view of the semiconductor device shown in FIG. 3.

FIG. 5 is a plan view of a layer in the semiconductor device shown in FIG. 3 where low-potential coils are formed.

FIG. 6 is a plan view of a layer in the semiconductor device shown in FIG. 3 where high-potential coils are formed.

FIG. 7 is a cross-sectional view taken along line VIII-VIII shown in FIG. 6.

FIG. 8 is an enlarged view (showing a separation structure) of region XIII shown in FIG. 7.

FIG. 9 is a diagram schematically showing an example of the layout of a transformer chip.

FIG. 10 is a diagram showing the configuration of an electronic device incorporated in the signal transmission device.

FIG. 11 is a diagram showing the configuration of the signal transmission device in the present disclosure.

FIG. 12 is a diagram showing the configuration of a driver-side logic circuit.

FIG. 13 is a table showing a correlation between the logic levels of output signals, determination result signals, a high-side signal, a low-side signal and terminal voltages and the state of a drive target switch.

FIG. 14 is a diagram showing the configuration of a vehicle which incorporates the electronic device.

### DESCRIPTION OF EMBODIMENTS

### Signal Transmission Device (Basic Configuration)

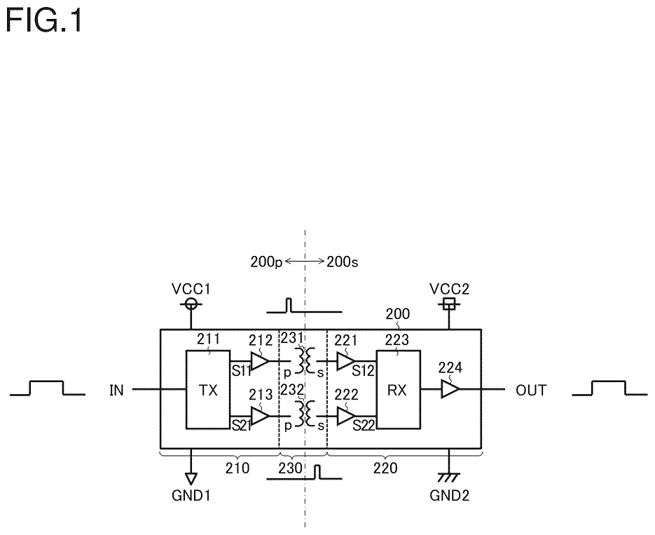

FIG. 1 is a diagram illustrating the basic configuration of a signal transmission device. The signal transmission device 200 of this configuration example is a semiconductor integrated circuit device (what is generally called an isolated gate driver IC) that, while isolating between a primary circuit system 200p (VCC1-GND1 system) and a secondary circuit system 200s (VCC2-GND2 system), transmits a pulse signal from the primary circuit system 200p to the secondary circuit system 200s to drive the gate of a switching device (unillustrated) provided in the secondary circuit system 200s. The signal transmission device 200 has, for example, a controller chip 210, a driver chip 220, and a transformer chip 230 sealed in a single package.

The controller chip 210 is a semiconductor chip that operates by being supplied with a supply voltage VCC1 (e.g., seven volts at the maximum with respect to GND1). The controller chip 210 has, for example, a pulse transmission circuit 211 and buffers 212 and 213 integrated in it.

The pulse transmission circuit 211 is a pulse generator that generates transmission pulse signals S11 and S21 according to an input pulse signal IN. More specifically, when indicating that the input pulse signal IN is at high level, the pulse transmission circuit 211 pulse-drives (outputs a single or a plurality of pulses in) the transmission pulse signal S11; when indicating that the input pulse signal IN is at low level, the pulse transmission circuit 211 pulse-drives the transmission pulse signal S21. That is, the pulse transmission circuit 211 pulse-drives either the transmission pulse signal S11 or S21 according to the logic level of the input pulse signal IN.

The buffer 212 receives the transmission pulse signal S11 from the pulse transmission circuit 211, and pulse-drives the transformer chip 230 (more specifically, a transformer 231).

The buffer 213 receives the transmission pulse signal S21 from the pulse transmission circuit 211, and pulse-drives the transformer chip 230 (more specifically, a transformer 232).

The driver chip 220 is a semiconductor chip that operates by being supplied with a supply voltage VCC2 (e.g., 30 volts at the maximum with respect to GND2). The driver chip 220 has, for example, buffers 221 and 222, a pulse reception circuit 223, and a driver 224 integrated in it.

The buffer 221 performs waveform shaping on a reception pulse signal S12 induced in the transformer chip 230 (specifically, the transformer 231), and outputs the result to the pulse reception circuit 223.

The buffer 222 performs waveform shaping on a reception pulse signal S22 induced in the transformer chip 230 (specifically, the transformer 232), and outputs the result to the pulse reception circuit 223.

According to the reception pulse signals S12 and S22 fed to it via the buffers 221 and 222, the pulse reception circuit 223 drives the driver 224 to generate an output pulse signal OUT. More specifically, the pulse reception circuit 223 drives the driver 224 to raise the output pulse signal OUT to high level in response to the reception pulse signal S12 being pulse-driven and to drop the output pulse signal OUT to low level in response to the reception pulse signal S22 being pulse-driven. That is, the pulse reception circuit 223 switches the logic level of the output pulse signal OUT according to the logic level of the input pulse signal IN. As the pulse reception circuit 223, for example, an RS flip-flop can be suitably used.

The driver 224 generates the output pulse signal OUT under the driving and control of the pulse reception circuit 223.

The transformer chip 230, while isolating between the controller chip 210 and the driver chip 220 on a direct-current basis using the transformers 231 and 232, outputs the transmission pulse signals S11 and S21 fed to the transformer chip 230 from the pulse transmission circuit 211 to, as the reception pulse signals S12 and S22, the pulse reception circuit 223. In the present description, “isolating on a direct-current basis” means leaving two elements to be isolated from each other unconnected by a conductor.

More specifically, the transformer 231 outputs, according to the transmission pulse signal S11 fed to the primary coil 231p, the reception pulse signal S12 from the secondary coil 231s. Likewise, the transformer 232 outputs, according to the transmission pulse signal S21 fed to the primary coil 232p, the reception pulse signal S22 from the secondary coil 232s.

In this way, owing to the characteristics of spiral coils used in isolated communication, the input pulse signal IN is split into two transmission pulse signals S11 and S21 (corresponding to a rise signal and a fall signal) to be transmitted via the two transformers 231 and 232 from the primary circuit system 200p to the secondary circuit system 200s.

Note that the signal transmission device 200 of this configuration example has, separately from the controller chip 210 and the driver chip 220, the transformer chip 230 that incorporates the transformers 231 and 232 alone, and those three chips are sealed in a single package.

With this configuration, the controller chip 210 and the driver chip 220 can each be formed by a common low-to middle-withstand-voltage process (with a withstand voltage of several volts to several tens of volts). This eliminates the need for a dedicated high-withstand-voltage process (with a withstand voltage of several kilovolts) and helps reduce manufacturing costs.

The signal transmission device 200 can be employed suitably, for example, in a power supply device or motor driving device in a vehicle-mounted device incorporated in a vehicle. Such a vehicle can be an engine vehicle or an electric vehicle (an xEV such as a BEV [battery electric vehicle], HEV [hybrid electric vehicle], PHEV/PHV [plug-in hybrid electric vehicle/plug-in hybrid vehicle], or FCEV/FCV [fuel cell electric vehicle/fuel cell vehicle]).

### Transformer Chip (Basic Structure)

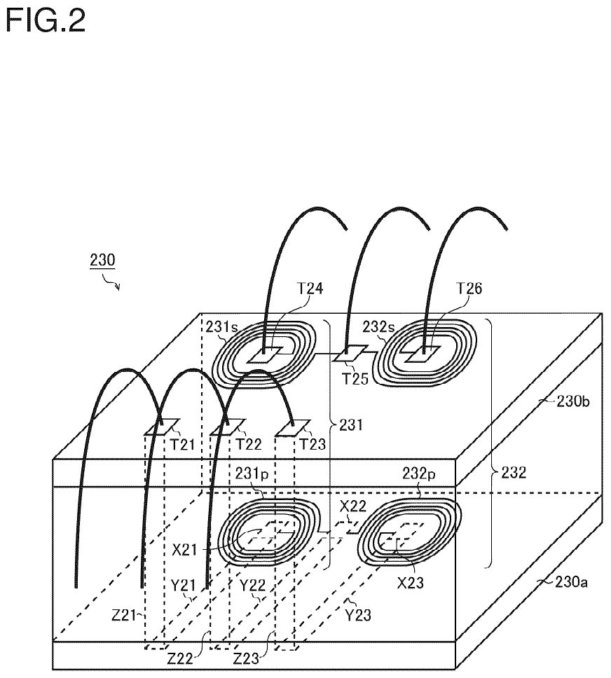

Next, the basic structure of the transformer chip 230 will be described. FIG. 2 is a diagram showing the basic structure of the transformer chip 230. In the transformer chip 230 shown there, the transformer 231 includes a primary coil 231p and a secondary coil 231s that face each other in the up-down direction; the transformer 232 includes a primary coil 232p and a secondary coil 232s that face each other in the up-down direction.

The primary coils 231p and 232p are both formed in a first wiring layer (lower layer) 230a in the transformer chip 230. The secondary coils 231s and 232s are both formed in a second wiring layer (the upper layer in the diagram) 230b in the transformer chip 230. The secondary coil 231s is disposed right above the primary coil 231p and faces the primary coil 231p; the secondary coil 232s is disposed right above the primary coil 232p and faces the primary coil 232p.

The primary coil 231p is laid in a spiral shape so as to encircle an internal terminal X21 clockwise, starting at the first terminal of the primary coil 231p, which is connected to the internal terminal X21. The second terminal of the primary coil 231p, which corresponds to its end point, is connected to an internal terminal X22. Likewise, the primary coil 232p is laid in a spiral shape so as to encircle an internal terminal X23 anticlockwise, starting at the first terminal of the primary coil 232p, which is connected to the internal terminal X23. The second terminal of the primary coil 232p, which corresponds to its end point, is connected to the internal terminal X22. The internal terminals X21, X22, and X23 are arrayed on a straight line in the illustrated order.

The internal terminal X21 is connected, via a wiring Y21 and a via Z21 both conductive, to an external terminal T21 in the second layer 230b. The internal terminal X22 is connected, via a wiring Y22 and a via Z22 both conductive, to an external terminal T22 in the second layer 230b. The internal terminal X23 is connected, via a wiring Y23 and a via Z23 both conductive, to an external terminal T23 in the second layer 230b. The external terminals T21 to T23 are disposed in a straight row and are used for wire-bonding with the controller chip 210.

The secondary coil 231s is laid in a spiral shape so as to encircle an external terminal T24 anticlockwise, starting at the first terminal of the secondary coil 231s, which is connected to the external terminal T24. The second terminal of the secondary coil 231s, which corresponds to its end point, is connected to an external terminal T25. Likewise, the secondary coil 232s is laid in a spiral shape so as to encircle an external terminal T26 clockwise, starting at the first terminal of the secondary coil 232s, which is connected to the external terminal T26. The second terminal of the secondary coil 232s, which corresponds to its end point, is connected to the external terminal T25. The external terminals T24, T25, and T26 are disposed in a straight row in the illustrated order and are used for wire-bonding with the driver chip 220.

The secondary coils 231s and 232s are AC-connected to the primary coils 231p and 232p, respectively, by magnetic coupling, and are DC-isolated from the primary coils 231p and 232p. That is, the driver chip 220 is AC-connected to the controller chip 210 via the transformer chip 230 and is DC-isolated from the controller chip 210 by the transformer chip 230.

### Transformer Chip (Two-Channel Type)

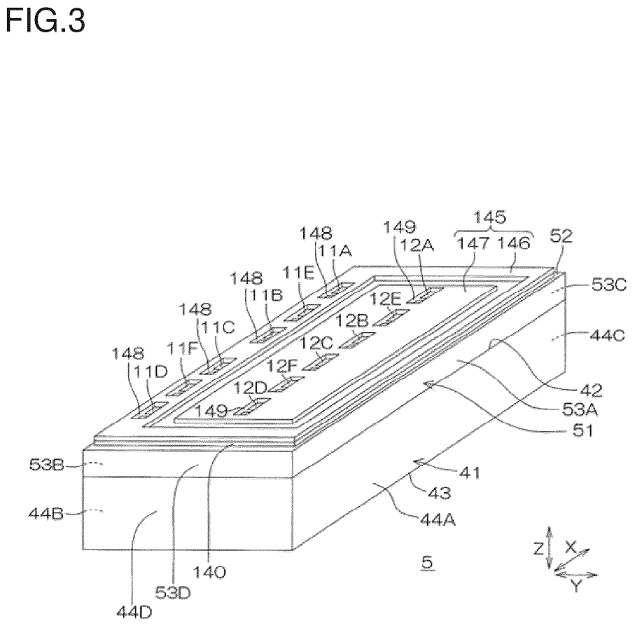

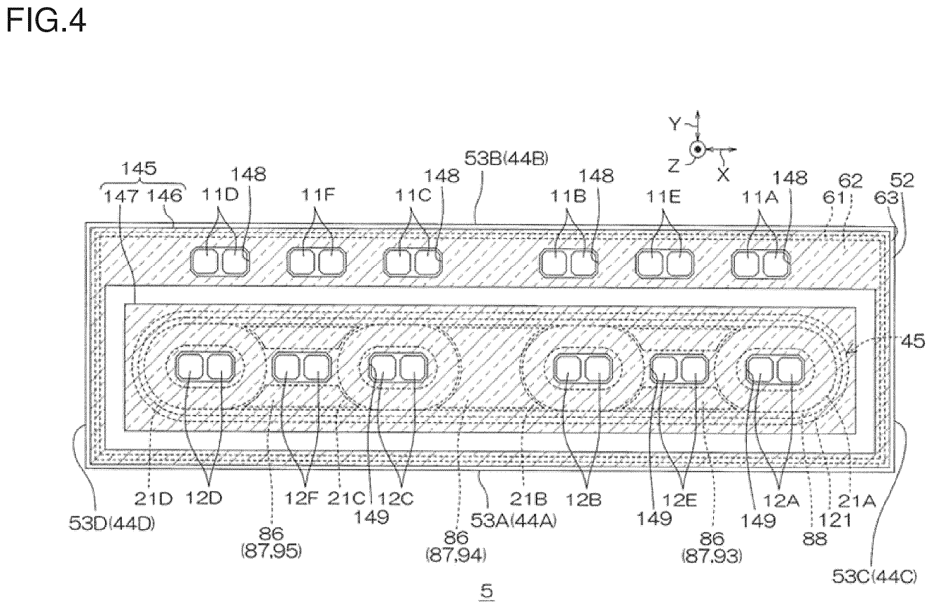

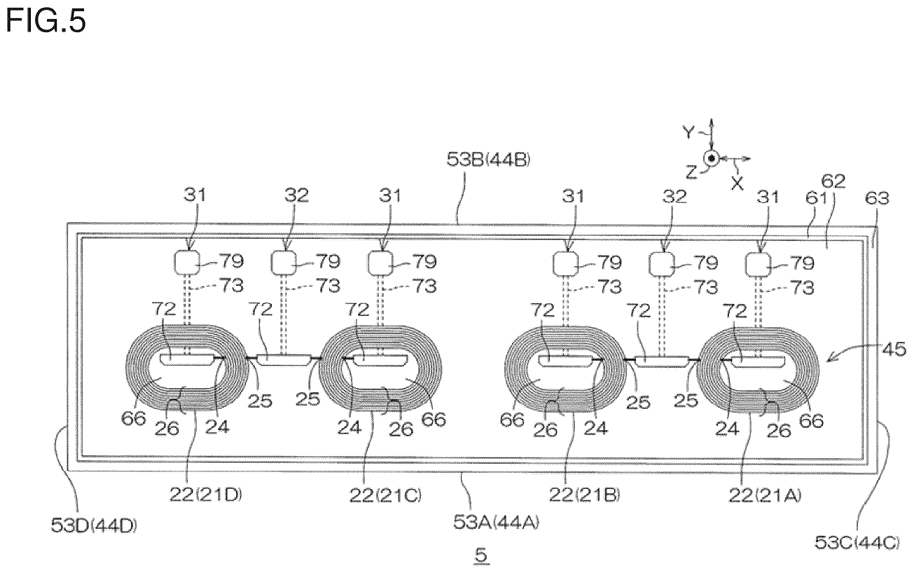

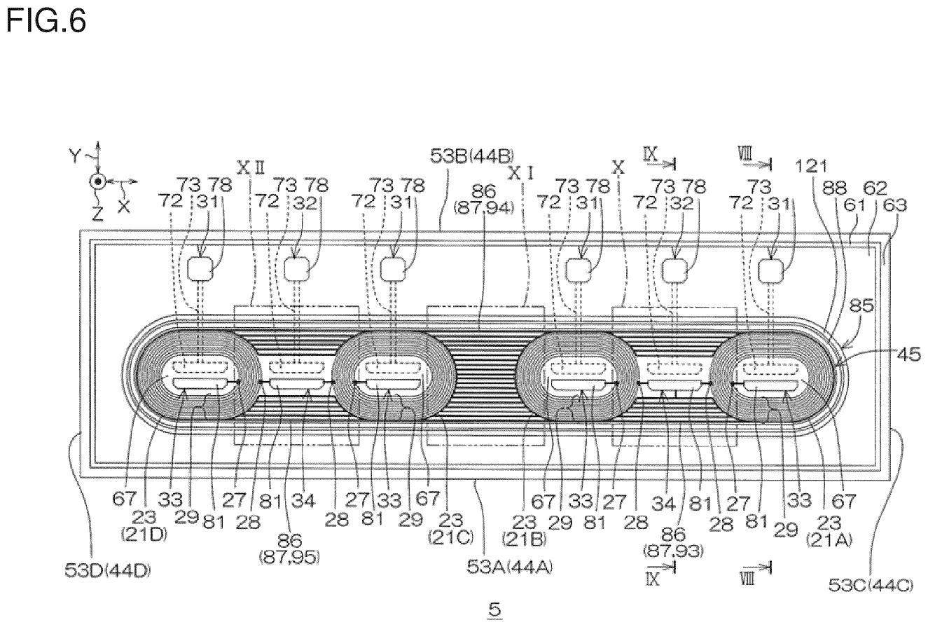

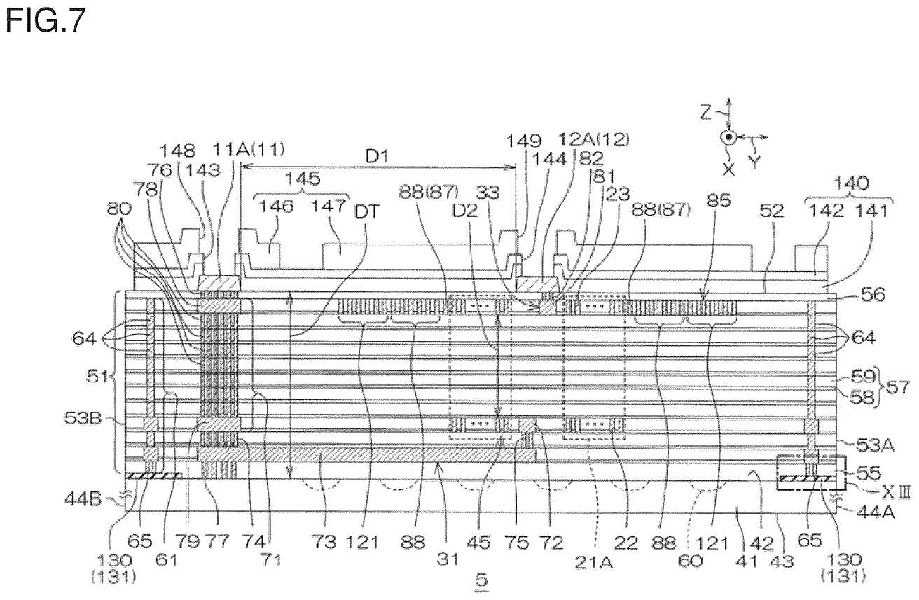

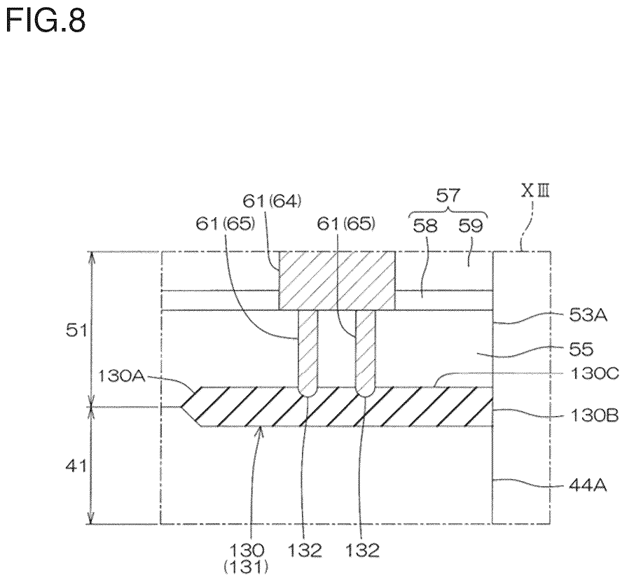

FIG. 3 is a perspective view of a semiconductor device 5 used as a two-channel transformer chip. FIG. 4 is a plan view of the semiconductor device 5 shown in FIG. 3. FIG. 5 is a plan view showing a layer in the semiconductor device 5 shown in FIG. 3 where low-potential coils 22 (corresponding to the primary coils of transformers) are formed. FIG. 6 is a plan view showing a layer in the semiconductor device 5 shown in FIG. 3 where high-potential coils 23 (corresponding to the secondary coils of transformers) are formed. FIG. 7 is a sectional view along line VIII-VIII shown in FIG. 6. FIG. 8 is an enlarged view of region XIII shown in FIG. 7, which shows a separation structure 130.

Referring to FIG. 3 to FIG. 7, the semiconductor device 5 includes a semiconductor chip 41 in the shape of a rectangular parallelepiped. The semiconductor chip 41 contains at least one of silicon, a wide band gap semiconductor, and a compound semiconductor.

The wide band gap semiconductor is a semiconductor with a band gap larger than that of silicon (about 1.12 eV). Preferably, the wide band gap semiconductor has a band gap of 2.0 eV or more. The wide band gap semiconductor can be SiC (silicon carbide). The compound semiconductor can be a III-V group compound semiconductor. The compound semiconductor can contain at least one of aluminum nitride (AlN), indium nitride (InN), gallium nitride (GaN), and gallium arsenide (GaAs).

In the embodiment, the semiconductor chip 41 includes a semiconductor substrate made of silicon. The semiconductor chip 41 can be an epitaxial substrate that has a stacked structure composed of a semiconductor substrate made of silicon and an epitaxial layer made of silicon. The semiconductor substrate can be of an n-type or p-type conductivity. The epitaxial layer can be of an n-type or p-type.

The semiconductor chip 41 has a first principal surface 42 at one side, a second principal surface 43 at the other side, and chip side walls 44A to 44D that connect the first and second principal surfaces 42 and 43 together. As seen in a plan view from the normal direction Z to them (hereinafter simply expressed as “as seen in a plan view”), the first and second principal surfaces 42 and 43 are each formed in a quadrangular shape (in the embodiment, in a rectangular shape).

The chip side walls 44A to 44D include a first chip side wall 44A, a second chip side wall 44B, a third chip side wall 44C, and a fourth chip side wall 44D. The first and second chip side walls 44A and 44B constitute the longer sides of the semiconductor chip 41. The first and second chip side walls 44A and 44B extend along a first direction X and face away from each other in a second direction Y. The third and fourth chip side walls 44C and 44D constitute the shorter sides of the semiconductor chip 41. The third and fourth chip side walls 44C and 44D extend in the second direction Y and face away from each other in the first direction X. The chip side walls 44A to 44D have polished surfaces.

The semiconductor device 5 further includes an insulation layer 51 formed on the first principal surface 42 of the semiconductor chip 41. The insulation layer 51 has an insulation principal surface 52 and insulation side walls 53A to 53D. The insulation principal surface 52 is formed in a quadrangular shape (in the embodiment, a rectangular shape) that fits the first principal surface 42 as seen in a plan view. The insulation principal surface 52 extends parallel to the first principal surface 42.

The insulation side walls 53A to 53D include a first insulation side wall 53A, a second insulation side wall 53B, a third insulation side wall 53C, and a fourth insulation side wall 53D. The insulation side walls 53A to 53D extend from the circumferential edge of the insulation principal surface 52 toward the semiconductor chip 41 and are continuous with the chip side walls 44A to 44D. Specifically, the insulation side walls 53A to 53D are formed to be flush with the chip side walls 44A to 44D. The insulation side walls 53A to 53D constitute polished surfaces that are flush with the chip side walls 44A to 44D.

The insulation layer 51 has a stacked structure of multilayer insulation layers that include a bottom insulation layer 55, a top insulation layer 56, and a plurality of (in the embodiment, eleven) interlayer insulation layers 57. The bottom insulation layer 55 is an insulation layer that directly covers the first principal surface 42. The top insulation layer 56 is an insulation layer that constitutes the insulation principal surface 52. The plurality of interlayer insulation layers 57 are insulation layers that are interposed between the bottom and top insulation layers 55 and 56. In the embodiment, the bottom insulation layer 55 has a single-layer structure that contains silicon oxide. In the embodiment, the top insulation layer 56 has a single-layer structure that contains silicon oxide. The bottom and top insulation layers 55 and 56 can each have a thickness of 1 μm or more but 3 μm or less (e.g., about 2 μm).

The plurality of interlayer insulation layers 57 each have a stacked structure that includes a first insulation layer 58 at the bottom insulation layer 55 side and a second insulation layer 59 at the top insulation layer 56 side. The first insulation layer 58 can contain silicon nitride. The first insulation layer 58 is formed as an etching stopper layer for the second insulation layer 59. The first insulation layer 58 can have a thickness of 0.1 μm or more but 1 μm or less (e.g., about 0.3 μm).

The second insulation layer 59 is formed on top of the first insulation layer 58 and contains an insulating material different from that of the first insulation layer 58. The second insulation layer 59 can contain silicon oxide. The second insulation layer 59 can have a thickness of 1 μm or more but 3 μm or less (e.g., about 2 μm). Preferably, the second insulation layer 59 is given a thickness larger than that of the first insulation layer 58.

The insulation layer 51 can have a total thickness DT of 5 μm or more but 50 μm or less. The insulation layer 51 can have any total thickness DT and any number of interlayer insulation layers 57 stacked together, which are adjusted according to the desired dielectric strength voltage (dielectric breakdown withstand voltage). The bottom insulation layer 55, the top insulation layer 56, and the interlayer insulation layers 57 can employ any insulating material, which is thus not limited to any particular insulating material.

The semiconductor device 5 includes a first functional device 45 formed in the insulation layer 51. The first functional device 45 includes one or a plurality of (in the embodiment, a plurality of) transformers 21 (corresponding to the transformers mentioned previously). That is, the semiconductor device 5 is a multichannel device that includes a plurality of transformers 21. The plurality of transformers 21 are formed in an inner part of the insulation layer 51, at intervals from the insulation side walls 53A to 53D. The plurality of transformers 21 are formed at intervals from each other in the first direction X.

Specifically, the plurality of transformers 21 include a first transformer 21A, a second transformer 21B, a third transformer 21C, and a fourth transformer 21D that are formed in this order from the insulation side wall 53C side to the insulation side wall 53D side as seen in a plan view. The plurality of transformers 21A to 21D have similar structures. In the following description, the structure of the first transformer 21A will be described as an example. No separate description will be given of the structures of the second, third, and fourth transformers 21B, 21C, and 21D, to which the description of the structure of the first transformer 21A is to be taken to apply.

Referring to FIG. 5 to FIG. 7, the first transformer 21A includes a low-potential coil 22 and a high-potential coil 23. The low-potential coil 22 is formed in the insulation layer 51. The high-potential coil 23 is formed in the insulation layer 51 so as to face the low-potential coil 22 in the normal direction Z. In the embodiment, the low-and high-potential coils 22 and 23 are formed in a region between the bottom and top insulation layers 55 and 56 (i.e., in the plurality of interlayer insulation layers 57).

The low-potential coil 22 is formed in the insulation layer 51, at the bottom insulation layer 55 (semiconductor chip 41) side, and the high-potential coil 23 is formed in the insulation layer 51, at the top insulation layer 56 (insulation principal surface 52) side with respect to the low-potential coil 22. That is, the high-potential coil 23 faces the semiconductor chip 41 across the low-potential coil 22. The low-and high-potential coils 22 and 23 can be disposed at any places. The high-potential coil 23 can face the low-potential coil 22 across one or more interlayer insulation layers 57.

The distance between the low-and high-potential coils 22 and 23 (i.e., the number of interlayer insulation layers 57 stacked together) is adjusted appropriately according to the dielectric strength voltage and electric field strength between the low-and high-potential coils 22 and 23. In the embodiment, the low-potential coil 22 is formed in the third interlayer insulation layer 57 as counted from the bottom insulation layer 55 side. In the embodiment, the high-potential coil 23 is formed in the first interlayer insulation layer 57 as counted from the top insulation layer 56 side.

The low-potential coil 22 is embedded in the interlayer insulation layer 57 so as to penetrate the first and second insulation layers 58 and 59. The low-potential coil 22 includes a first inner end 24, a first outer end 25, and a first spiral portion 26 that is patterned in a spiral shape between the first inner and outer ends 24 and 25. The first spiral portion 26 is patterned in a spiral shape that extends in an elliptical (oval) shape as seen in a plan view. The part of the first spiral portion 26 that forms its inner circumferential edge defines a first inner region 66 that is in an elliptical shape as seen in a plan view.

The first spiral portion 26 can have a number of turns of 5 or more but 30 or less. The first spiral portion 26 can have a width of 0.1 μm or more but 5 μm or less. Preferably, the first spiral portion 26 has a width of 1 μm or more but 3 μm or less. The width of the first spiral portion 26 is defined by its width in the direction orthogonal to the spiraling direction. The first spiral portion 26 has a first winding pitch of 0.1 μm or more but 5 μm or less. Preferably, the first winding pitch is 1 μm or more but 3 μm or less. The first winding pitch is defined by the distance between two parts of the first spiral portion 26 that are adjacent to each other in the direction orthogonal to the spiraling direction.

The first spiral portion 26 can have any winding shape and the first inner region 66 can have any planar shape, which are thus not limited to those shown in FIG. 5 etc. The first spiral portion 26 can be wound in a polygonal shape, such as a triangular or quadrangular shape, or in a circular shape as seen in a plan view. The first inner region 66 can be defined, so as to fit the winding shape of the first spiral portion 26, in a polygonal shape, such as a triangular or quadrangular shape, or in a circular shape as seen in a plan view.

The low-potential coil 22 can contain at least one of titanium, titanium nitride, copper, aluminum, and tungsten. The low-potential coil 22 can have a stacked structure composed of a barrier layer and a body layer. The barrier layer defines a recessed space in the interlayer insulation layer 57. The barrier layer can contain at least one of titanium and titanium nitride. The body layer can contain at least one of copper, aluminum, and tungsten.

The high-potential coil 23 is embedded in the interlayer insulation layer 57 so as to penetrate the first and second insulation layers 58 and 59. The high-potential coil 23 includes a second inner end 27, a second outer end 28, and a second spiral portion 29 that is patterned in a spiral shape between the second inner and outer ends 27 and 28. The second spiral portion 29 is patterned in a spiral shape that extends in an elliptical (oval) shape as seen in a plan view. The part of the second spiral portion 29 that forms its inner circumferential edge defines a second inner region 67 that is in an elliptical shape as seen in a plan view in the embodiment. The second inner region 67 in the second spiral portion 29 faces the first inner region 66 in the first spiral portion 26 in the normal direction Z.

The second spiral portion 29 can have a number of turns of 5 or more but 30 or less. The number of turns of the second spiral portion 29 relative to that of the first spiral portion 26 is adjusted according to the target value of voltage boosting. Preferably, the number of turns of the second spiral portion 29 is larger than that of the first spiral portion 26. Needless to say, the number of turns of the second spiral portion 29 can be smaller than or equal to that of the first spiral portion 26.

The second spiral portion 29 can have a width of 0.1 μm or more but 5 μm or less. Preferably, the second spiral portion 29 has a width of 1 μm or more but 3 μm or less. The width of the second spiral portion 29 is defined by its width in the direction orthogonal to the spiraling direction. Preferably, the width of the second spiral portion 29 is equal to the width of the first spiral portion 26.

The second spiral portion 29 can have a second winding pitch of 0.1 μm or more but 5 μm or less. Preferably, the second winding pitch is 1 μm or more but 3 μm or less. The second winding pitch is defined by the distance between two parts of the second spiral portion 29 that are adjacent to each other in the direction orthogonal to the spiraling direction. Preferably, the second winding pitch is equal to the first winding pitch of the first spiral portion 26.

The second spiral portion 29 can have any winding shape and the second inner region 67 can have any planar shape, which are thus not limited to those shown in FIG. 6 etc. The second spiral portion 29 can be wound in a polygonal shape, such as a triangular or quadrangular shape, or in a circular shape as seen in a plan view. The second inner region 67 can be defined, so as to fit the winding shape of the second spiral portion 29, in a polygonal shape, such as a triangular or quadrangular shape, or in a circular shape as seen in a plan view.

Preferably, the high-potential coil 23 is formed of the same conductive material as the low-potential coil 22. That is, preferably, like the low-potential coil 22, the high-potential coil 23 includes a barrier layer and a body layer.

Referring to FIG. 4, the semiconductor device 5 includes a plurality of (in the diagram, twelve) low-potential terminals 11 and a plurality of (in the diagram, twelve) high-potential terminals 12. The plurality of low-potential terminals 11 are electrically connected to the low-potential coils 22 of the corresponding transformers 21A to 21D respectively. The plurality of high-potential terminals 12 are electrically connected to the high-potential coils 23 of the corresponding transformers 21A to 21D respectively.

The plurality of low-potential terminals 11 are formed on the insulation principal surface 52 of the insulation layer 51. Specifically, the plurality of low-potential terminals 11 are formed in a second insulation side wall 53B side region, at an interval from the plurality of transformers 21A to 21D in the second direction Y, and are arrayed at intervals from each other in the first direction X.

The plurality of low-potential terminals 11 include a first low-potential terminal 11A, a second low-potential terminal 11B, a third low-potential terminal 11C, a fourth low-potential terminal 11D, a fifth low-potential terminal 11E, and a sixth low-potential terminal 11F. Actually, in the embodiment, two each of the plurality of low-potential terminals 11A to 11F are formed. The plurality of low-potential terminals 11A to 11F may each include any number of terminals.

The first low-potential terminal 11A faces the first transformer 21A in the second direction Y as seen in a plan view. The second low-potential terminal 11B faces the second transformer 21B in the second direction Y as seen in a plan view. The third low-potential terminal 11C faces the third transformer 21C in the second direction Y as seen in a plan view. The fourth low-potential terminal 11D faces the fourth transformer 21D in the second direction Y as seen in a plan view. The fifth low-potential terminal 11E is formed in a region between the first and second low-potential terminals 11A and 11B as seen in a plan view. The sixth low-potential terminal 11F is formed in a region between the third and fourth low-potential terminals 11C and 11D as seen in a plan view.

The first low-potential terminal 11A is electrically connected to the first inner end 24 of the first transformer 21A (low-potential coil 22). The second low-potential terminal 11B is electrically connected to the first inner end 24 of the second transformer 21B (low-potential coil 22). The third low-potential terminal 11C is electrically connected to the first inner end 24 of the third transformer 21C (low-potential coil 22). The fourth low-potential terminal 11D is electrically connected to the first inner end 24 of the fourth transformer 21D (low-potential coil 22).

The fifth low-potential terminal 11E is electrically connected to the first outer end 25 of the first transformer 21A (low-potential coil 22) and to the first outer end 25 of the second transformer 21B (low-potential coil 22). The sixth low-potential terminal 11F is electrically connected to the first outer end 25 of the third transformer 21C (low-potential coil 22) and to the first outer end 25 of the fourth transformer 21D (low-potential coil 22).

The plurality of high-potential terminals 12 are formed on the insulation principal surface 52 of the insulation layer 51, at an interval from the plurality of low-potential terminals 11. Specifically, the plurality of high-potential terminals 12 are formed in a first insulation side wall 53A side region, at an interval from the plurality of low-potential terminals 11 in the second direction Y, and are arrayed at intervals from each other in the first direction X.

The plurality of high-potential terminals 12 are formed in regions close to the corresponding transformers 21A to 21D, respectively, as seen in a plan view. The high-potential terminals 12 being close to the transformers 21A to 21D means that, as seen in a plan view, the distance between the high-potential terminals 12 and the transformers 21 is smaller than the distance between the low-potential terminals 11 and the high-potential terminals 12.

Specifically, as seen in a plan view, the plurality of high-potential terminals 12 are formed at intervals from each other along the first direction X so as to face the plurality of transformers 21A to 21D along the first direction X. More specifically, as seen in a plan view, the plurality of high-potential terminals 12 are formed at intervals from each other along the first direction X so as to be located in the second inner regions 67 in the high-potential coils 23 and in regions between adjacent high-potential coils 23. As a result, as seen in a plan view, the plurality of high-potential terminals 12 are, along with the transformers 21A to 21D, arrayed in one row along the first direction X.

The plurality of high-potential terminals 12 include a first high-potential terminal 12A, a second high-potential terminal 12B, a third high-potential terminal 12C, a fourth high-potential terminal 12D, a fifth high-potential terminal 12E, and a sixth high-potential terminal 12F. Actually, in the embodiment, two each of the plurality of high-potential terminals 12A to 12F are formed. The plurality of high-potential terminals 12A to 12F may each include any number of terminals.

The first high-potential terminal 12A is formed in the second inner region 67 in the first transformer 21A (high-potential coil 23) as seen in a plan view. The second high-potential terminal 12B is formed in the second inner region 67 in the second transformer 21B (high-potential coil 23) as seen in a plan view. The third high-potential terminal 12C is formed in the second inner region 67 in the third transformer 21C (high-potential coil 23) as seen in a plan view. The fourth high-potential terminal 12D is formed in the second inner region 67 in the fourth transformer 21D (high-potential coil 23) as seen in a plan view. The fifth high-potential terminal 12E is formed in a region between the first and second transformers 21A and 21B as seen in a plan view. The sixth high-potential terminal 12F is formed in a region between the third and fourth transformers 21C and 21D as seen in a plan view.

The first high-potential terminal 12A is electrically connected to the second inner end 27 of the first transformer 21A (high-potential coil 23). The second high-potential terminal 12B is electrically connected to the second inner end 27 of the second transformer 21B (high-potential coil 23). The third high-potential terminal 12C is electrically connected to the second inner end 27 of the third transformer 21C (high-potential coil 23). The fourth high-potential terminal 12D is electrically connected to the second inner end 27 of the fourth transformer 21D (high-potential coil 23).

The fifth high-potential terminal 12E is electrically connected to the second outer end 28 of the first transformer 21A (high-potential coil 23) and to the second outer end 28 of the second transformer 21B (high-potential coil 23). The sixth high-potential terminal 12F is electrically connected to the second outer end 28 of the third transformer 21C (high-potential coil 23) and to the second outer end 28 of the fourth transformer 21D (high-potential coil 23).

Referring to FIG. 5 and FIG. 7, the semiconductor device 5 includes a first low-potential wiring 31, a second low-potential wiring 32, a first high-potential wiring 33, and a second high-potential wiring 34, all formed in the insulation layer 51. Actually, in the embodiment, a plurality of first low-potential wirings 31, a plurality of second low-potential wirings 32, a plurality of first high-potential wirings 33, and a plurality of second high-potential wirings 34 are formed.

The first and second low-potential wirings 31 and 32 hold the low-potential coils 22 of the first and second transformers 21A and 21B at equal potentials. The first and second low-potential wirings 31 and 32 also hold the low-potential coils 22 of the third and fourth transformers 21C and 21D at equal potentials. In the embodiment, the first and second low-potential wirings 31 and 32 hold the low-potential coils 22 of all the transformers 21A to 21D at equal potentials.

The first and second high-potential wirings 33 and 34 hold the high-potential coils 23 of the first and second transformers 21A and 21B at equal potentials. The first and second high-potential wirings 33 and 34 also hold the high-potential coils 23 of the third and fourth transformers 21C and 21D at equal potentials. In the embodiment, the first and second high-potential wirings 33 and 34 hold the high-potential coils 23 of all the transformers 21A to 21D at equal potentials.

The plurality of first low-potential wirings 31 are electrically connected respectively to the corresponding low-potential terminals 11A to 11D and to the first inner ends 24 of the corresponding transformers 21A to 21D (low-potential coils 22). The plurality of first low-potential wirings 31 have similar structures. In the following description, the structure of the first low-potential wiring 31 connected to the first low-potential terminal 11A and to the first transformer 21A will be described as an example. No separate description will be given of the structures of the other first low-potential wirings 31, to which the description of the structure of the first low-potential wiring 31 connected to the first transformer 21A is to be taken to apply.

The first low-potential wiring 31 includes a through wiring 71, a low-potential connection wiring 72, a lead wiring 73, a first connection plug electrode 74, a second connection plug electrode 75, one or a plurality of (in this embodiment, a plurality of) pad plug electrodes 76, and one or a plurality of (in this embodiment, a plurality of) substrate plug electrodes 77.

Preferably, the through wiring 71, the low-potential connection wiring 72, the lead wiring 73, the first connection plug electrode 74, the second connection plug electrode 75, the pad plug electrodes 76, and the substrate plug electrodes 77 are formed of the same conductive material as the low-potential coil 22 and the like. That is, preferably, like the low-potential coil 22 and the like, the through wiring 71, the low-potential connection wiring 72, the lead wiring 73, the first connection plug electrode 74, the second connection plug electrode 75, the pad plug electrodes 76, and the substrate plug electrodes 77 each include a barrier layer and a body layer.

The through wiring 71 penetrates a plurality of interlayer insulation layers 57 in the insulation layer 51 and extends in a columnar shape along the normal direction Z. In the embodiment, the through wiring 71 is formed in a region between the bottom and top insulation layers 55 and 56 in the insulation layer 51. The through wiring 71 has a top end part at the top insulation layer 56 side and a bottom end part at the bottom insulation layer 55 side. The top end part of the through wiring 71 is formed in the same interlayer insulation layer 57 as the high-potential coil 23 and is covered by the top insulation layer 56. The bottom end part of the through wiring 71 is formed in the same interlayer insulation layer 57 as the low-potential coil 22.

In the embodiment, the through wiring 71 includes a first electrode layer 78, a second electrode layer 79, and a plurality of wiring plug electrodes 80. In the through wiring 71, the first and second electrode layers 78 and 79 and the wiring plug electrodes 80 are formed of the same conductive material as the low-potential coil 22 and the like. That is, like the low-potential coil 22 and the like, the first and second electrode layers 78 and 79 and the wiring plug electrodes 80 each include a barrier layer and a body layer.

The first electrode layer 78 constitutes the top end part of the through wiring 71. The second electrode layer 79 constitutes the bottom end part of the through wiring 71. The first electrode layer 78 is formed as an island, and faces the low-potential terminal 11 (first low-potential terminal 11A) in the normal direction Z. The second electrode layer 79 is formed as an island, and faces the first electrode layer 78 in the normal direction Z.

The plurality of wiring plug electrodes 80 are embedded respectively in the plurality of interlayer insulation layers 57 located in a region between the first and second electrode layers 78 and 79. The plurality of wiring plug electrodes 80 are stacked together from the bottom insulation layer 55 to the top insulation layer 56 so as to be electrically connected together, and electrically connect together the first and second electrode layers 78 and 79. The plurality of wiring plug electrodes 80 each have a plane area smaller than the plane area of either of the first and second electrode layers 78 and 79.

The number of layers stacked in the plurality of wiring plug electrodes 80 is equal to the number of layers stacked in the plurality of interlayer insulation layers 57. In the embodiment, six wiring plug electrodes 80 are embedded in interlayer insulation layers 57 respectively, and any number of wiring plug electrodes 80 can be embedded in interlayer insulation layers 57 respectively. Needless to say, one or a plurality of wiring plug electrodes 80 can be formed that penetrates a plurality of interlayer insulation layers 57.

The low-potential connection wiring 72 is formed in the same interlayer insulation layer 57 as the low-potential coil 22, in the first inner region 66 in the first transformer 21A (low-potential coil 22). The low-potential connection wiring 72 is formed as an island and faces the high-potential terminal 12 (first high-potential terminal 12A) in the normal direction Z. Preferably, the low-potential connection wiring 72 has a plane area larger than the plane area of the wiring plug electrode 80. The low-potential connection wiring 72 is electrically connected to the first inner end 24 of the low-potential coil 22.

The lead wiring 73 is formed in the interlayer insulation layer 57, in a region between the semiconductor chip 41 and the through wiring 71. In the embodiment, the lead wiring 73 is formed in the first interlayer insulation layer 57 as counted from the bottom insulation layer 55. The lead wiring 73 has a first end part at one side, a second end part at the other side, and a wiring part that connects together the first and second end parts. The first end part of the lead wiring 73 is located in a region between the semiconductor chip 41 and the bottom end part of the through wiring 71. The second end part of the lead wiring 73 is located in a region between the semiconductor chip 41 and the low-potential connection wiring 72. The wiring part extends along the first principal surface 42 of the semiconductor chip 41 and extends in the shape of a stripe in a region between the first and second end parts.

The first connection plug electrode 74 is formed in the interlayer insulation layer 57, in a region between the through wiring 71 and the lead wiring 73, and is electrically connected to the through wiring 71 and to the first end part of the lead wiring 73. The second connection plug electrode 75 is formed in the interlayer insulation layer 57, in a region between the low-potential connection wiring 72 and the lead wiring 73, and is electrically connected to the low-potential connection wiring 72 and to the second end part of the lead wiring 73.

The plurality of pad plug electrodes 76 are formed in the top insulation layer 56, in a region between the low-potential terminal 11 (first low-potential terminal 11A) and the through wiring 71, and are electrically connected to the low-potential terminal 11 and to the top end part of the through wiring 71. The plurality of substrate plug electrodes 77 are formed in the bottom insulation layer 55, in a region between the semiconductor chip 41 and the lead wiring 73. In the embodiment, the substrate plug electrodes 77 are formed in a region between the semiconductor chip 41 and the first end part of the lead wiring 73 and are electrically connected to the semiconductor chip 41 and to the first end part of the lead wiring 73.

Referring to FIG. 6 and FIG. 7, the plurality of first high-potential wirings 33 are connected respectively to the corresponding high-potential terminals 12A to 12D and to the second inner ends 27 of the corresponding transformers 21A to 21D (high-potential coils 23). The plurality of first high-potential wirings 33 have similar structures. In the following description, the structure of the first high-potential wiring 33 connected to the first high-potential terminal 12A and to the first transformer 21A will be described as an example. No description will be given of the structures of the other first high-potential wirings 33, to which the description of the structure of the first high-potential wiring 33 connected to the first transformer 21A is to be taken to apply.

The first high-potential wiring 33 includes a high-potential connection wiring 81 and one or a plurality of (in this embodiment, a plurality of) pad plug electrodes 82. Preferably, the high-potential connection wiring 81 and the pad plug electrodes 82 are formed of the same conductive material as the low-potential coil 22 and the like. That is, preferably, like the low-potential coil 22 and the like, the high-potential connection wiring 81 and the pad plug electrodes 82 each include a barrier layer and a body layer.

The high-potential connection wiring 81 is formed in the same interlayer insulation layer 57 as the high-potential coil 23, in the second inner region 67 in the high-potential coil 23. The high-potential connection wiring 81 is formed as an island, and faces the high-potential terminal 12 (first high-potential terminal 12A) in the normal direction Z. The high-potential connection wiring 81 is electrically connected to the second inner end 27 of the high-potential coil 23. The high-potential connection wiring 81 is formed at an interval from the low-potential connection wiring 72 as seen in a plan view, and does not face the low-potential connection wiring 72 in the normal direction Z. This results in an increased insulation distance between the low-and high-potential connection wirings 72 and 81 and hence an increased dielectric strength voltage in the insulation layer 51.

The plurality of pad plug electrodes 82 are formed in the top insulation layer 56, in a region between the high-potential terminal 12 (first high-potential terminal 12A) and the high-potential connection wiring 81, and are electrically connected to the high-potential terminal 12 and to the high-potential connection wiring 81. The plurality of pad plug electrodes 82 each have a plane area smaller than the plane area of the high-potential connection wiring 81 as seen in a plan view.

Referring to FIG. 7, preferably, the distance D1 between the low-and high-potential terminals 11 and 12 is larger than the distance D2 between the low-and high-potential coils 22 and 23 (D2<D1). Preferably, the distance D1 is larger than the total thickness DT of the plurality of interlayer insulation layers 57 (DT<D1). The ratio D2/D1 of the distance D2 to the distance D1 can be 0.01 or more but 0.1 or less. Preferably, the distance D1 is 100 μm or more but 500 μm or less. The distance D2 can be 1 μm or more but 50 μm or less. Preferably, the distance D2 is 5 μm or more but 25 μm or less. The distances D1 and D2 can have any value, which are adjusted appropriately according to the desired dielectric strength voltage.

Referring to FIG. 6 and FIG. 7, the semiconductor device 5 has a dummy pattern 85 that is embedded in the insulation layer 51 so as to be located around the transformers 21A to 21D as seen in a plan view.

The dummy pattern 85 is formed in a pattern different (discontinuous) from that of either of the high-and low-potential coils 23 and 22, and is independent of the transformers 21A to 21D. That is, the dummy pattern 85 does not function as part of the transformers 21A to 21D. The dummy pattern 85 is formed as a shield conductor layer that shields electric fields between the low-and high-potential coils 22 and 23 in the transformers 21A to 21D to suppress electric field concentration on the high-potential coil 23. In the embodiment, the dummy pattern 85 is patterned at a line density per unit area that is equal to the line density of the high-potential coil 23. The line density of the dummy pattern 85 being equal to the line density of the high-potential coil 23 means that the line density of the dummy pattern 85 falls within the range of ±20% of the line density of the high-potential coil 23.

The dummy pattern 85 can be formed at any depth in the insulation layer 51, which is adjusted according to the electric field strength to be attenuated. Preferably, the dummy pattern 85 is formed in a region closer to the high-potential coil 23 than to the low-potential coil 22 with respect to the normal direction Z. The dummy pattern 85 being closer to the high-potential coil 23 with respect to the normal direction Z means that, with respect to the normal direction Z, the distance between the dummy pattern 85 and the high-potential coil 23 is smaller than the distance between the dummy pattern 85 and the low-potential coil 22.

In that way, electric field concentration on the high-potential coil 23 can be suppressed properly. The smaller the distance between the dummy pattern 85 and the high-potential coil 23 with respect to the normal direction Z, the more effectively electric field concentration on the high-potential coil 23 can be suppressed. Preferably, the dummy pattern 85 is formed in the same interlayer insulation layer 57 as the high-potential coil 23. In that way, electric field concentration on the high-potential coil 23 can be suppressed more properly. The dummy pattern 85 includes a plurality of dummy patterns that are in varying electrical states. The dummy pattern 85 can include a high-potential dummy pattern.

The high-potential dummy pattern 86 can be formed at any depth in the insulation layer 51, which is adjusted according to the electric field strength to be attenuated.

Preferably, the high-potential dummy pattern 86 is formed in a region closer to the high-potential coil 23 than to the low-potential coil 22 with respect to the normal direction Z. The high-potential dummy pattern 86 being closer to the high-potential coil 23 with respect to the normal direction Z means that, with respect to the normal direction Z, the distance between the high-potential dummy pattern 86 and the high-potential coil 23 is smaller than the distance between the high-potential dummy pattern 86 and the low-potential coil 22.

The dummy pattern 85 includes a floating dummy pattern that is formed in an electrically floating state in the insulation layer 51 so as to be located around the transformers 21A to 21D.

In the embodiment, the floating dummy pattern is patterned in dense lines so as to partly cover and partly expose a region around the high-potential coil 23 as seen in a plan view. The floating dummy pattern can be formed so as to have ends or no ends.

The floating dummy pattern can be formed at any depth in the insulation layer 51, which is adjusted according to the electric field strength to be attenuated.

Any number of floating lines can be provided, which is adjusted according to the electric field strength to be attenuated. The floating dummy pattern can include a plurality of floating dummy patterns.

Referring to FIG. 7, the semiconductor device 5 includes a second functional device 60 that is formed in the first principal surface 42 of the semiconductor chip 41 in a device region 62. The second functional device 60 is formed using a superficial part of the first principal surface 42 and/or a region on the first principal surface 42 of the semiconductor chip 41 and is covered by the insulation layer 51 (bottom insulation layer 55). In FIG. 7, the second functional device 60 is shown in a simplified form by broken lines indicated in a superficial part of the first principal surface 42.

The second functional device 60 is electrically connected to a low-potential terminal 11 via a low-potential wiring, and is electrically connected to a high-potential terminal 12 via a high-potential wiring. Except that the low-potential wiring is patterned in the insulation layer 51 so as to be connected to the second functional device 60, it has a similar structure to the first low-potential wiring 31 (second low-potential wiring 32). Except that the high-potential wiring is patterned in the insulation layer 51 so as to be connected to the second functional device 60, it has a similar structure to the first high-potential wiring 33 (second high-potential wiring 34). No description will be given of the low-and high-potential wirings associated with the second functional device 60.

The second functional device 60 can include at least one of a passive device, a semiconductor rectification device, and a semiconductor switching device. The second functional device 60 can include a circuit network comprising a selective combination of any two or more of a passive device, a semiconductor rectification device, and a semiconductor switching device. The circuit network can constitute part or the whole of an integrated circuit.

The passive device can include a semiconductor passive device. The passive device can include one or both of a resistor and a capacitor. The semiconductor rectification device can include at least one of a pn-junction diode, a PIN diode, a Zener diode, a Schottky barrier diode, and a fast-recovery diode. The semiconductor switching device can include at least one of a BJT (bipolar junction transistor), a MISFET (metal-insulator-semiconductor field-effect transistor), an IGBT (insulated-gate bipolar junction transistor), and a JFET (junction field-effect transistor).

Referring to FIG. 5 to FIG. 7, the semiconductor device 5 further includes a sealing conductor 61 embedded in the insulation layer 51. The sealing conductor 61 is embedded in the form of walls in the insulation layer 51, at intervals from the insulation side walls 53A to 53D as seen in a plan view and partitions the insulation layer 51 into the device region 62 and an outer region 63. The sealing conductor 61 prevents moisture entry and crack development from the outer region 63 to the device region 62.

The device region 62 is a region that includes the first functional device 45 (plurality of transformers 21), the second functional device 60, the plurality of low-potential terminals 11, the plurality of high-potential terminals 12, the first low-potential wirings 31, the second low-potential wirings 32, the first high-potential wirings 33, the second high-potential wirings 34, and the dummy pattern 85. The outer region 63 is a region outside the device region 62.

The sealing conductor 61 is electrically isolated from the device region 62. Specifically, the sealing conductor 61 is electrically isolated from the first functional device 45 (plurality of transformers 21), the second functional device 60, the plurality of low-potential terminals 11, the plurality of high-potential terminals 12, the first low-potential wirings 31, the second low-potential wirings 32, the first high-potential wirings 33, the second high-potential wirings 34, and the dummy pattern 85. More specifically, the sealing conductor 61 is held in an electrically floating state. The sealing conductor 61 does not form a current path connected to the device region 62.

The sealing conductor 61 is formed in the shape of a stripe along the insulation side walls 53A to 53D as seen in a plan view. In the embodiment, the sealing conductor 61 is formed in a quadrangular ring shape (specifically, a rectangular ring shape) as seen in a plan view. Thus, the sealing conductor 61 defines the device region 62 in a quadrangular shape (specifically, a rectangular shape) as seen in a plan view. Furthermore, the sealing conductor 61 defines the outer region 63 in a quadrangular ring shape (specifically, a rectangular ring shape) surrounding the device region 62 as seen in a plan view.

Specifically, the sealing conductor 61 has a top end part at the insulation principal surface 52 side, a bottom end part at the semiconductor chip 41 side, and a wall part that extends in the form of walls between the top and bottom end parts. In the embodiment, the top end part of the sealing conductor 61 is formed at an interval from the insulation principal surface 52 toward the semiconductor chip 41 and is located in the insulation layer 51. In the embodiment, the top end part of the sealing conductor 61 is covered by the top insulation layer 56. The top end part of the sealing conductor 61 can be covered by one or a plurality of interlayer insulation layers 57. The top end part of the sealing conductor 61 can be exposed through the top insulation layer 56. The bottom end part of the sealing conductor 61 is formed at an interval from the semiconductor chip 41 toward the top end part.

Thus, in the embodiment, the sealing conductor 61 is embedded in the insulation layer 51 so as to be located at the semiconductor chip 41 side of the plurality of low-potential terminals 11 and the plurality of high-potential terminals 12. Moreover, in the insulation layer 51, the sealing conductor 61 faces, in the direction parallel to the insulation principal surface 52, the first functional device 45 (plurality of transformers 21), the first low-potential wirings 31, the second low-potential wirings 32, the first high-potential wirings 33, the second high-potential wirings 34, and the dummy pattern 85. In the insulation layer 51, the sealing conductor 61 can face, in the direction parallel to the insulation principal surface 52, part of the second functional device 60.

The sealing conductor 61 includes a plurality of sealing plug conductors 64 and one or a plurality of (in the embodiment, a plurality of) sealing via conductors 65. Any number of sealing via conductors 65 may be provided. Of the plurality of sealing plug conductors 64, the top sealing plug conductor 64 constitutes the top end part of the sealing conductor 61. The plurality of sealing via conductors 65 constitute the bottom end part of the sealing conductor 61. Preferably, the sealing plug conductors 64 and the sealing via conductors 65 are formed of the same conductive material as the low-potential coil 22. That is, preferably, like the low-potential coil 22 and the like, the sealing plug conductors 64 and the sealing via conductors 65 each include a barrier layer and a body layer.

The plurality of sealing plug conductors 64 are embedded in the plurality of interlayer insulation layers 57 respectively, and are each formed in a quadrangular ring shape (specifically, a rectangular ring shape) surrounding the device region 62 as seen in a plan view. The plurality of sealing plug conductors 64 are stacked together from the bottom insulation layer 55 to the top insulation layer 56 so as to be connected together. The number of layers stacked in the plurality of sealing plug conductors 64 is equal to the number of layers in the plurality of interlayer insulation layers 57. Needless to say, one or a plurality of sealing plug conductors 64 may be formed that penetrates a plurality of interlayer insulation layers 57.

So long as a set of a plurality of sealing plug conductors 64 constitutes one ring-shaped sealing conductor 61, not all the sealing plug conductors 64 need be formed in a ring shape. For example, at least one of the plurality of sealing plug conductors 64 can be formed so as to have ends. Or at least one of the plurality of sealing plug conductors 64 may be divided into a plurality of strip-shaped portions with ends. However, with consideration given to the risk of moisture entry and crack development into the device region 62, preferably, the plurality of sealing plug conductors 64 are formed so as to have no ends (in a ring shape).

The plurality of sealing via conductors 65 are formed in the bottom insulation layer 55, in a region between the semiconductor chip 41 and the sealing plug conductors 64. The plurality of sealing via conductors 65 are formed at an interval from the semiconductor chip 41 and are connected to the sealing plug conductors 64. The plurality of sealing via conductors 65 have a plane area smaller than the plane area of the sealing plug conductors 64. In a case where a single sealing via conductor 65 is formed, the single sealing via conductors 65 can have a plane area equal to or larger than the plane area of the sealing plug conductors 64.

The sealing conductor 61 can have a width of 0.1 μm or more but 10 μm or less. Preferably, the sealing conductor 61 has a width of 1 μm or more but 5 μm or less. The width of the sealing conductor 61 is defined by its width in the direction orthogonal to the direction in which it extends.

Referring to FIG. 7 and FIG. 8, the semiconductor device 5 further includes the separation structure 130 that is interposed between the semiconductor chip 41 and the sealing conductor 61 and that electrically isolates the sealing conductor 61 from the semiconductor chip 41. Preferably, the separation structure 130 includes an insulator. In the embodiment, the separation structure 130 is a field insulation film 131 formed on the first principal surface 42 of the semiconductor chip 41.

The field insulation film 131 includes at least one of an oxide film (silicon oxide film) and a nitride film (silicon nitride film). Preferably, the field insulation film 131 is a LOCOS (local oxidation of silicon) film as one example of an oxide film that is formed through oxidation of the first principal surface 42 of the semiconductor chip 41. The field insulation film 131 can have any thickness so long as it can insulate between the semiconductor chip 41 and the sealing conductor 61. The field insulation film 131 can have a thickness of 0.1 μm or more but 5 μm or less.

The separation structure 130 is formed on the first principal surface 42 of the semiconductor chip 41, and extends in the shape of a stripe along the sealing conductor 61 as seen in a plan view. In the embodiment, the separation structure 130 is formed in a quadrangular ring shape (specifically, a rectangular ring shape) as seen in a plan view. The separation structure 130 has a connection portion 132 to which the bottom end part of the sealing conductor 61 (i.e., the sealing via conductors 65) is connected. The connection portion 132 can form an anchor portion into which the bottom end part of the sealing conductor 61 (i.e., the sealing via conductors 65) is anchored toward the semiconductor chip 41. Needless to say, the connection portion 132 can be formed to be flush with the principal surface of the separation structure 130.

The separation structure 130 includes an inner end part 130A at the device region 62 side, an outer end part 130B at the outer region 63 side, and a main body part 130C between the inner and outer end parts 130A and 130B. As seen in a plan view, the inner end part 130A defines the region where the second functional device 60 is formed (i.e., the device region 62). The inner end part 130A can be formed integrally with an insulation film (not illustrated) formed on the first principal surface 42 of the semiconductor chip 41.

The outer end part 130B is exposed on the chip side walls 44A to 44D of the semiconductor chip 41, and is continuous with the chip side walls 44A to 44D of the semiconductor chip 41. More specifically, the outer end part 130B is formed so as to be flush with the chip side walls 44A to 44D of the semiconductor chip 41. The outer end part 130B constitutes a polished surface between, to be flush with, the chip side walls 44A to 44D of the semiconductor chip 41 and the insulation side walls 53A to 53D of the insulation layer 51. Needless to say, an embodiment is also possible where the outer end part 130B is formed within the first principal surface 42 at intervals from the chip side walls 44A to 44D.

The main body part 130C has a flat surface that extends substantially parallel to the first principal surface 42 of the semiconductor chip 41. The main body part 130C has the connection portion 132 to which the bottom end part of the sealing conductor 61 (i.e., the sealing via conductors 65) is connected. The connection portion 132 is formed in the main body part 130C, at intervals from the inner and outer end parts 130A and 130B. The separation structure 130 can be implemented in many ways other than in the form of a field insulation film 131.

Referring to FIG. 7, the semiconductor device 5 further includes an inorganic insulation layer 140 formed on the insulation principal surface 52 of the insulation layer 51 so as to cover the sealing conductor 61. The inorganic insulation layer 140 can be called a passivation layer. The inorganic insulation layer 140 protects the insulation layer 51 and the semiconductor chip 41 from above the insulation principal surface 52.

In the embodiment, the inorganic insulation layer 140 has a stacked structure composed of a first inorganic insulation layer 141 and a second inorganic insulation layer 142. The first inorganic insulation layer 141 can contain silicon oxide. Preferably, the first inorganic insulation layer 141 contains USG (undoped silicate glass), which is undoped silicon oxide. The first inorganic insulation layer 141 can have a thickness of 50 nm or more but 5000 nm or less. The second inorganic insulation layer 142 can contain silicon nitride. The second inorganic insulation layer 142 can have a thickness of 500 nm or more but 5000 nm or less. Increasing the total thickness of the inorganic insulation layer 140 helps increase the dielectric strength voltage above the high-potential coils 23.

In a configuration where the first inorganic insulation layer 141 is made of USG and the second inorganic insulation layer 142 is made of silicon nitride, USG has the higher dielectric breakdown voltage (V/cm) than silicon nitride. In view of this, when thickening the inorganic insulation layer 140, it is preferable to form the first inorganic insulation layer 141 thicker than the second inorganic insulation layer 142.

The first inorganic insulation layer 141 can contain at least one of BPSG (boron-doped phosphor silicate glass) and PSG (phosphorus silicate glass) as examples of silicon oxide. In that case, however, since the silicon oxide contains a dopant (boron or phosphorus), for an increased dielectric strength voltage above the high-potential coils 23, it is particularly preferable to form the first inorganic insulation layer 141 of USG. Needless to say, the inorganic insulation layer 140 can have a single-layer structure composed of either the first or second inorganic insulation layer 141 or 142.

The inorganic insulation layer 140 covers the entire area of the sealing conductor 61, and has a plurality of low-potential pad openings 143 and a plurality of high-potential pad openings 144 that are formed in a region outside the sealing conductor 61. The plurality of low-potential pad openings 143 expose the plurality of low-potential terminals 11 respectively. The plurality of high-potential pad openings 144 expose the plurality of high-potential terminals 12 respectively. The inorganic insulation layer 140 can have overlap parts that overlap circumferential edge parts of the low-potential terminals 11. The inorganic insulation layer 140 can have overlap parts that overlap circumferential edge parts of the high-potential terminals 12.

The semiconductor device 5 further includes an organic insulation layer 145 that is formed on the inorganic insulation layer 140. The organic insulation layer 145 can contain photosensitive resin. The organic insulation layer 145 can contain at least one of polyimide, polyamide, and polybenzoxazole. In the embodiment, the organic insulation layer 145 contains polyimide. The organic insulation layer 145 can have a thickness of 1 μm or more but 50 μm or less.

Preferably, the organic insulation layer 145 has a thickness larger than the total thickness of the inorganic insulation layer 140. Moreover, preferably, the inorganic and organic insulation layers 140 and 145 together have a total thickness larger than the distance D2 between the low-and high-potential coils 22 and 23. In that case, preferably, the inorganic insulation layer 140 has a total thickness of 2 μm or more but 10 μm or less. Preferably, the organic insulation layer 145 has a thickness of 5 μm or more but 50 μm or less. Such structures help suppress an increase in the thicknesses of the inorganic and organic insulation layers 140 and 145 while appropriately increasing the dielectric strength voltage above the high-potential coil 23 owing to the stacked film of the inorganic and organic insulation layers 140 and 145.

The organic insulation layer 145 includes a first part 146 that covers a low-potential side region and a second part 147 that covers a high-potential side region. The first part 146 covers the sealing conductor 61 across the inorganic insulation layer 140. The first part 146 has a plurality of low-potential terminal openings 148 through which the plurality of low-potential terminals 11 (low-potential pad openings 143) are respectively exposed in a region outside the sealing conductor 61. The first part 146 can have overlap parts that overlap circumferential edges (overlap parts) of the low-potential pad openings 143.

The second part 147 is formed at an interval from the first part 146 and exposes the inorganic insulation layer 140 between the first and second parts 146 and 147. The second part 147 has a plurality of high-potential terminal openings 149 through which the plurality of high-potential terminals 12 (high-potential pad openings 144) are respectively exposed. The second part 147 can have overlap parts that overlap circumferential edges (overlap parts) of the high-potential pad openings 144.

The second part 147 covers the transformers 21A to 21D and the dummy pattern 85 together. Specifically, the second part 147 covers the plurality of high-potential coils 23, the plurality of high-potential terminals 12, a first high-potential dummy pattern 87, a second high-potential dummy pattern 88, and a floating dummy pattern 121 together.

The present disclosure can be implemented in any other embodiments. The embodiment described above deals with an example where a first functional device 45 and a second functional device 60 are formed. An embodiment is however also possible that only has a second functional device 60, with no first functional device 45. In that case, the dummy pattern 85 may be omitted. This structure provides, with respect to the second functional device 60, effects similar to those mentioned in connection with the first embodiment (except those associated with the dummy pattern 85).

That is, in a case where a voltage is applied to the second functional device 60 via the low-and high-potential terminals 11 and 12, it is possible to suppress unnecessary conduction between the high-potential terminal 12 and the sealing conductor 61. Likewise, in a case where a voltage is applied to the second functional device 60 via the low-and high-potential terminals 11 and 12, it is possible to suppress unnecessary conduction between the low-potential terminal 11 and the sealing conductor 61.

The embodiment described above deals with an example where a second functional device 60 is formed. The second functional device 60, however, is not essential and can be omitted.

The embodiment described above deals with an example where a dummy pattern 85 is formed. The dummy pattern 85 however is not essential and can be omitted.

The embodiment described above deals with an example where the first functional device 45 is of a multichannel type that includes a plurality of transformers 21. It is however also possible to employ a single-channel first functional device 45 that includes a single transformer 21.

### Transformer Layout

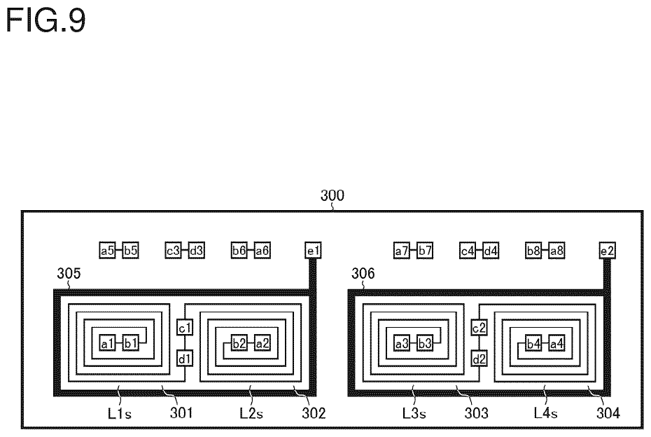

FIG. 9 is a plan view (top view) schematically showing one example of transformer layout in a two-channel transformer chip 300 (corresponding to the semiconductor device 5 described previously). The transformer chip 300 shown there includes a first transformer 301, a second transformer 302, a third transformer 303, a fourth transformer 304, a first guard ring 305, a second guard ring 306, pads a1 to a8, pads b1 to b8, pads c1 to c4, and pads d1 to d4.

In the transformer chip 300, the pads a1 and b1 are connected to one terminal of the secondary coil L1s of the first transformer 301, and the pads c1 and d1 are connected to the other terminal of that secondary coil L1s. The pads a2 and b2 are connected to one terminal of the secondary coil L2s of the second transformer 302, and the pads c1 and d1 are connected to the other terminal of that secondary coil L2s.

Moreover, the pads a3 and b3 are connected to one terminal of the secondary coil L3s of the third transformer 303, and the pads c2 and d2 are connected to the other terminal of that secondary coil L3s. The pads a4 and b4 are connected to one terminal of the secondary coil L4s of the fourth transformer 304, and the pads c2 and d2 are connected to the other terminal of that secondary coil L4s.

FIG. 9 does not show any of the primary coils of the first, second, third, and fourth transformers 301, 302, 303, and 304. The primary coils basically have structures similar to those of the secondary coils L1s to L4s respectively, and are disposed right below the secondary coils L1s to L4s, respectively, so as to face them.

Specifically, the pads a5 and b5 are connected to one terminal of the primary coil of the first transformer 301, and the pads c3 and d3 are connected to the other terminal of that primary coil. Likewise, the pads a6 and b6 are connected to one terminal of the primary coil of the second transformer 302, and the pads c3 and d3 are connected to the other terminal of that primary coil.

Likewise, the pads a7 and b7 are connected to one terminal of the primary coil of the third transformer 303, and the pads c4 and d4 are connected to the other terminal of that primary coil. Likewise, the pads a8 and b8 are connected to one terminal of the primary coil of the fourth transformer 304, and the pads c4 and d4 are connected to the other terminal of that primary coil.

The pads a5 to a8, the pads b5 to b8, the pads c3 and c4, and the pads d3 and d4 mentioned above are each led from inside the transformer chip 300 to its surface across an unillustrated via.

Of the plurality of pads mentioned above, the pads a1 to a8 each correspond to a first current feed pad, and the pads b1 to b8 each correspond to a first voltage measurement pad; the pads c1 to c4 each correspond to a second current feed pad, and the pads d1 to d4 each correspond to a second voltage measurement pad.

Thus, the transformer chip 300 of this configuration example permits, during its defect inspection, accurate measurement of the series resistance component across each coil. It is thus possible not only to reject defective products with a broken wire in a coil but also to appropriately reject defective products with an abnormal resistance value in a coil (e.g., a midway short circuit between coils), and hence to prevent defective products from being distributed in the market.

For a transformer chip 300 that has passed the defect inspection mentioned above, the plurality of pads described above can be used for connection with a primary-side chip and a secondary-side chip (e.g., the controller chip 210 and the driver chip 220 described previously).

Specifically, the pads a1 and b1, the pads a2 and b2, the pads a3 and b3, and the pads a4 and b4 can each be connected to one of the signal input and output terminals of the secondary-side chip; the pads c1 and d1 and the pads c2 and d2 can each be connected to a common voltage application terminal (GND2) of the secondary-side chip.

On the other hand, the pads a5 and b5, the pads a6 and b6, the pads a7 and b7, and the pads a8 and b8 can each be connected to one of the signal input and output terminals of the primary-side chip; the pads c3 and d3 and the pads c4 and d4 can each be connected to a common voltage application terminal (GND1) of the primary-side chip.

Here, as shown in FIG. 9, the first to fourth transformers 301 to 304 are so arranged as to be coupled for each signal transmission direction. In terms of what is shown in the diagram, for example, the first and second transformers 301 and 302, which transmit a signal from the primary-side chip to the secondary-side chip, are coupled into a first pair by the first guard ring 305. Likewise, for example, the third and fourth transformers 303 and 304, which transmit a signal from the secondary-side chip to the primary-side chip, are coupled into a second pair by the second guard ring 306.

Such coupling is intended, in a structure where the primary and secondary coils of each of the first to fourth transformers 301 to 304 are formed so as to be stacked on each other in the up-down direction of the substrate of the transformer chip 300, to obtain a desired withstand voltage between the primary and secondary coils. The first and second guard rings 305 and 306 are, however, not essential elements.

The first and second guard rings 305 and 306 can be connected via pads e1 and e2, respectively, to a low-impedance wiring such as a grounded terminal.

In the transformer chip 300, the pads c1 and d1 are shared between the secondary coils L1s and L2s. The pads c2 and d2 are shared between the secondary coils L3s and L4s. The pads c3 and d3 are shared between the primary coils L1p and L2p. The pads c4 and d4 are shared between the primary coils that correspond to them respectively. This configuration helps reduce the number of pads and helps make the transformer chip 300 compact.

Moreover, as shown in FIG. 9, the primary and secondary coils of the first to fourth transformers 301 to 304 are preferably each wound in a rectangular shape (or, with the corners rounded, in a running-track shape) as seen in a plan view of the transformer chip 300. This configuration helps increase the area over which the primary and secondary coils overlap each other and helps enhance the transmission efficiency across the transformers.

Needless to say, the illustrated transformer layout is merely an example; any number of coils of any shape can be disposed in any layout, and pads can be disposed in any layout. Any of the chip structure, transformer layouts, etc. described above can be applied to semiconductor devices in general that have a coil integrated in a semiconductor chip.

### About Electronic Device 400

The signal transmission device 200 described above can be utilized in an electronic device 400. The electronic device 400 and a signal transmission device 200X and a signal transmission device 200Y which correspond to the signal transmission device 200 will be described below. The signal transmission device 200Y will first be described as a comparative example of the signal transmission device 200X in the present disclosure. The signal transmission device 200X in the present disclosure will then be described.

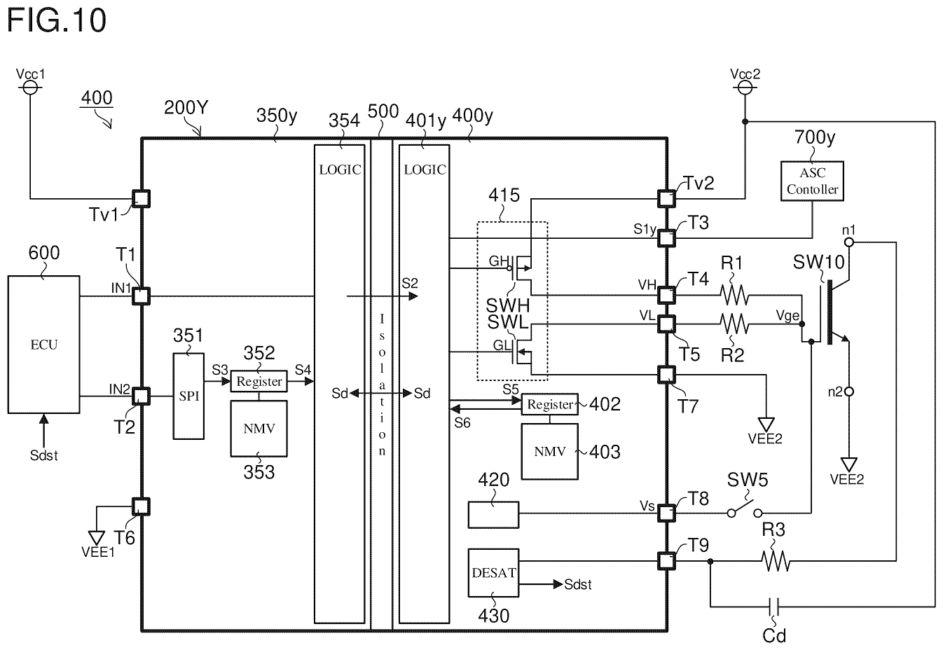

FIG. 10 is a diagram showing the configuration of the electronic device 400 incorporated in the signal transmission device 200Y. The electronic device 400 of the present configuration example is a type of motor driving device which converts direct-current power supplied from an unillustrated in-vehicle battery into alternating-current power to drive a motor (not shown).

As shown in FIG. 10, the electronic device 400 of the present configuration example includes an ECU (Electronic Control Unit) 600, a drive-side ASC (Active Short Circuit) controller 700y, the signal transmission device 200Y and a plurality of discrete components (in the FIG. 10, a drive target switch SW10, resistors R1 to R3, a switch SW5, a diode d5 and capacitors C3 and C4).

The ECU 600 is a means for comprehensively performing electrical control on the electronic device 400 and a vehicle A (see FIG. 14 which will be described later) incorporated in the electronic device 400. The ECU 600 generates input signals IN1 and IN2 and inputs the input signals IN1 and IN2 to the signal transmission device 200Y (more specifically, external terminals T1 and T2 which will be described later).

The drive-side ASC controller 700y generates an ASC signal S1y, and inputs the ASC signal S1y to the signal transmission device 200Y (more specifically, an external terminal T3 which will be described later). The ASC signal S1y is a digital signal which can have two values, that is, a high level and a low level. When an active short-circuit function which will be described later is performed, the drive-side ASC controller 700y switches the ASC signal S1y high. During a normal operation (when the active short-circuit function is not performed), a driver chip 400y switches the ASC signal S1y low.

The signal transmission device 200Y is a gate driver circuit which drives and controls the drive target switch SW10. The signal transmission device 200Y receives inputs of the input signals IN1 and IN2 to generate a drive voltage Vge. The details of the signal transmission device 200Y will be described later.

The drive target switch SW10 is an IGBT (insulated gate bipolar transistor). The gate of the drive target switch SW10 receives an input of the drive voltage Vge. The collector of the drive target switch SW10 is connected to a predetermined node n1. The emitter of the drive target switch SW10 is connected to a predetermined node n2.

The node n1 is connected to, for example, an application end of a high-side power supply voltage (not shown). The node n2 is connected to an application end of a low-side power supply voltage (=reference voltage VEE2).

The drive target switch SW10 is turned on and off according to the drive voltage Vge. Specifically, when the drive voltage Vge exceeds the on-threshold voltage of the drive target switch SW10, the drive target switch SW10 is turned on. During the on period of the drive target switch SW10, a current between the emitter and the collector corresponding to the voltage value of the drive voltage Vge flows. On the other hand, when the drive voltage Vge falls below the on-threshold voltage of the drive target switch SW10, the drive target switch SW10 is turned off. Here, the current between the emitter and the collector does not flow.

Then, the configuration of the signal transmission device 200Y will be described in detail. The signal transmission device 200Y is configured to transmit, while insulating an area between a primary circuit system (VCC1-VEE1) and a secondary circuit system (VCC2-VEE2), a gate drive signal from the primary circuit system to the secondary circuit system.

The signal transmission device 200Y includes terminals (in the figure, external terminals T1 to T9, a primary-side power supply terminal Tv1 and a secondary-side power supply terminal Tv2) as means for communicating with the outside.

The external terminal T1 receives an input of the input signal IN1 from the ECU 600. The external terminal T2 receives an input of the input signal IN2 from the ECU 600. The external terminal T3 receives an input of the ASC signal S1y from the drive-side ASC controller 700y.

The external terminal T4 is connected to the first end of the resistor R1. The external terminal T5 is connected to the first end of the resistor R2. The second ends of the resistor R1 and the resistor R2 are connected to the gate of the drive target switch SW10.

The external terminal T6 is connected to the application end of a reference voltage VEE1. The external terminal T7 is connected to the application end of the reference voltage VEE2.

The external terminal T8 is connected to the first end of the switch SW5. The second end of the switch SW5 is connected to the gate of the drive target switch SW10. The switch SW5 is configured to be able to switch the first and second ends thereof between an electrically conductive state (on) and an electrically disconnected state (off). The switch SW5 is basically off except a soft turn-on operation which will be described later.

The external terminal T9 is connected to the first end of the capacitor C3 and the first end of the resistor R3. The second end of the resistor R3 is connected to the anode of a diode d1. The cathode of the diode d1 is connected to the node n1. The second end of the capacitor C3 is connected to the node n2, the first end of the capacitor C4 and the application end of a secondary-side power supply voltage VCC2. The second end of the capacitor C4 is connected to the application end of the reference voltage VEE2.

The primary-side power supply terminal Tv1 is connected to the application end of a primary-side power supply voltage VCC1. The secondary-side power supply terminal Tv2 is connected to the application end of the secondary-side power supply voltage VCC2.

When the switch SW5 is off, the drive voltage Vge is generated at the connection node of the resistors R1 and R2. In other words, it is also said that the signal transmission device 200Y controls voltages generated at the external terminals T4 and T5 to change the drive voltage Vge and thereby drives and controls the drive target switch SW10.

The primary-side power supply terminal Tv1 is a power supply terminal in the primary circuit system (=controller chip 350y which will be described later). The primary circuit system receives the supply of the power supply voltage VCC1 via the primary-side power supply terminal Tv1. The secondary-side power supply terminal Tv2 is a power supply terminal in the secondary circuit system (=driver chip 400y which will be described later). The secondary circuit system receives the supply of the secondary-side power supply voltage VCC2 via the secondary-side power supply terminal Tv2.

The secondary-side power supply voltage VCC2 is higher than the primary-side power supply voltage VCC1. The reference voltage VEE1 is a constant voltage which is lower than the primary-side power supply voltage VCC1. The reference voltage VEE2 is a constant voltage which is lower than the secondary-side power supply voltage VCC2.

The signal transmission device 200Y includes the controller chip 350y, the driver chip 400y and a transformer chip 500. The signal transmission device 200Y is a semiconductor integrated circuit device which seals the controller chip 350y, the driver chip 400y and the transformer chip 500 into one package.

The controller chip 350y corresponds to the primary circuit system 200p described previously. The controller chip 350y is a controller chip formed by integrating a controller which has the function of generating the signals. The controller chip 350y is driven by receiving the supply of the power supply voltage VCC1. The controller chip 350y generates, based on the input signals IN1 and IN2, a PWM (Pulse Width Modulation) signal S2 and a data signal Sd. The details of the controller chip 350y are as follows.

The controller chip 350y includes an SPI (Serial Peripheral Interface) controller 301, a register 352, a nonvolatile memory 353 and a controller-side logic circuit 354.

The SPI controller 351 receives an input of the input signal IN2 from the ECU 600 via the external terminal T2. SPI communication is performed between the ECU 600 and the SPI controller 351. Although for ease of description, the external terminal T2 is shown as one terminal in the figures, for example, the external terminal T2 can be interpreted to include a plurality of terminals such as a chip select signal terminal, a clock signal terminal, an MOSI (Master Out Slave In) signal terminal and an MISO [Master-In Slave-Out] signal terminal. The input signal IN2 includes predetermined setting values and the like necessary for various operations of the signal transmission device 200Y.

The SPI controller 351 inputs a control signal S3 to the register 352 based on the input signal IN2. The control signal S3 includes the setting values and the like included in the input signal IN2. The register 352 receives an input of the input signal IN2 to store the setting values and the like therein in a volatile manner. Here, the register 352 can store the setting values and the like in the nonvolatile memory 353 in a nonvolatile manner.

The register 352 can access the nonvolatile memory 353 according to the control signal S3 to read predetermined information (the setting values and the like) from the nonvolatile memory 353. The register 352 generates a control signal S4 which includes the information read from the nonvolatile memory 353 and the setting values and the like stored therein. Then, the register 352 inputs the control signal S4 to the controller-side logic circuit 354.

The controller-side logic circuit 354 receives an input of the input signal IN1 via the external terminal T1. The controller-side logic circuit 354 also receives an input of the control signal S4 from the register 352.

The controller-side logic circuit 354 generates the PWM signal S2 based on the input signal IN1. The controller-side logic circuit 354 also generates the data signal Sd based on the control signal S4.

The PWM signal S2 is a pulse width modulation signal for controlling the drive of the drive target switch SW10. The timing of the turning on and off of the drive target switch SW10 is determined by the rising edge and the falling edge of the PWM signal S2. The on period of the drive target switch SW10 is determined according to the duty ratio f the PWM signal S2.

The data signal Sd is a signal which includes the information (the information read from the nonvolatile memory 353 by the register 352 and the setting values and the like) included in the control signal S4. The data signal Sd is transmitted between the controller-side logic circuit 354 and a driver-side logic circuit 401y in accordance with serial communication.

The PWM signal S2 and the data signal Sd are input from the controller-side logic circuit 354 to the transformer chip 500 (more specifically, a primary winding which will be described later).

The transformer chip 500 includes a plurality of primary windings and a plurality of secondary windings (not shown). The transformer chip 500 establishes transmission and reception of signals between the controller chip 350y and the driver chip 400y while insulating an area between the controller chip 350y and the driver chip 400y based on a direct current via the primary windings and the secondary windings.

The primary windings of the transformer chip 500 are connected to the controller chip 350y. The secondary windings of the transformer chip 500 are connected to the driver chip 400y.

The PWM signal S2 and the data signal Sd input to the primary windings of the transformer chip 500 are transmitted to the secondary windings and are input to the driver chip 400y.

The driver chip 400y corresponds to the secondary circuit system 200s described previously. A driver for drive control of the drive target switch SW10 is integrated into the driver chip 400y.

The driver chip 400y is driven by receiving the supply of the secondary-side power supply voltage VCC2. The driver chip 400y controls the drive voltage Vge based on the input PWM signal S2. A specific description will be given below.

The driver chip 400y includes the driver-side logic circuit 401y, a register 402, an output stage 415, a nonvolatile memory 403, a soft turn-on circuit 420 and a DESAT protection circuit 430.

The driver-side logic circuit 401y receives an input of the PWM signal S2. The driver-side logic circuit 401y generates a high-side signal GH and a low-side signal GL corresponding to the PWM signal S2.

The driver-side logic circuit 401y receives an input of the data signal Sd to generate a control signal S5 and inputs the control signal S5 to the register 402. The control signal S5 includes predetermined information (such as the information described above) included in the data signal Sd. The register 402 receives an input of the control signal S5, and stores the information included in the control signal S5 therein in a volatile manner. Here, the register 402 stores the information included in the control signal S5 in the nonvolatile memory 403 in a nonvolatile manner.

The register 402 can access the nonvolatile memory 403 according to the control signal S5 to read the predetermined information stored in the nonvolatile memory 403. Then, the register 402 can store the information read from the nonvolatile memory 403 therein in a volatile manner. The register 402 generates a control signal S6 such that the control signal S6 includes the information stored therein and inputs the control signal S6 to the driver-side logic circuit 401y at an arbitrary timing.

The output stage 415 receives inputs of the high-side signal GH and the low-side signal GL. The output stage 415 drives the drive target switch SW10 based on the high-side signal GH and the low-side signal GL. A specific description will be given below.

The output stage 415 includes a high-side switch SWH and a low-side switch SWL. The high-side switch SWH is a P-channel MOSFET (Metal Oxide Semiconductor Field Effect Transistor). The gate of the high-side switch SWH receives an input of the high-side signal GH from the driver-side logic circuit 401y. The source of the high-side switch SWH is connected to the secondary-side power supply terminal Tv2. The drain of the high-side switch SWH is connected to the external terminal T4.

The low-side switch SWL is an N-channel MOSFET. The gate of the low-side switch SWL receives an input of the low-side signal GL from the driver-side logic circuit 401y. The source of the low-side switch SWL is connected to the external terminal T5. The drain of the low-side switch SWL is connected to the external terminal T7.

For example, when the drive target switch SW10 is turned on (when the drive voltage Vge is switched high), the driver-side logic circuit 401y turns on the high-side switch SWH and turns off the low-side switch SWL. In other words, the high-side signal GH and the low-side signal GL are switched low. In this way, the secondary-side power supply voltage VCC2 is supplied to the external terminal T4, and thus the drive voltage Vge is switched high. Then, the drive target switch SW10 is turned on.

For example, when the drive target switch SW10 is turned off (when the drive voltage Vge is switched low), the driver-side logic circuit 401y turns off the high-side switch SWH and turns on the low-side switch SWL. In other words, the high-side signal GH and the low-side signal GL are switched high. In this way, the reference voltage VEE2 is supplied to the external terminal T5, and thus the drive voltage Vge is switched low. Then, the drive target switch SW10 is turned off.

For example, when the drive target switch SW10 is brought into a gate open state, the driver-side logic circuit 401y turns off the high-side switch SWH and the low-side switch SWL. In other words, the high-side signal GH is switched high, and the low-side signal GL is switched low. The gate of the drive target switch SW10 is brought into a floating state (=high impedance state). In this way, the drive target switch SW10 is brought into the gate open state.

During a normal operation, the driver-side logic circuit 401y receives an input of the PWM signal S2 to generate the high-side signal GH and the low-side signal GL. On the other hand, when the active short-circuit function is performed, the driver-side logic circuit 401y ignores the PWM signal S2 and generates the high-side signal GH and the low-side signal GL based on the control signal S6. The details of the active short-circuit function will be described later.

The soft turn-on circuit 420 generates a soft turn-on voltage Vs. The soft turn-on voltage Vs is generated such that its voltage value is gradually increased with a predetermined slew rate. The soft turn-on circuit 420 applies the soft turn-on voltage Vs to the external terminal T8.

The driver-side logic circuit 401y brings the drive target switch SW10 into the gate open state to turn on the switch SW5, and thereby can supply the soft turn-on voltage Vs to the gate of the drive target switch SW10. When the soft turn-on voltage Vs is supplied to the gate of the drive target switch SW10, the drive target switch SW10 is soft turned on. The details of the soft turning on of the drive target switch SW10 will be described later.

The DESAT protection circuit 430 is a circuit which monitors an SAT (saturation) voltage for the drive target switch SW10 to protect the drive target switch SW10 from an overcurrent and an overvoltage. The SAT voltage refers to a voltage between the base and the emitter during the on period of the drive target switch SW1. The DESAT protection circuit 430 causes a predetermined current to flow between the collector and the emitter during the on period of the drive target switch SW1. Here, a voltage is generated across the resistor R3. The DESAT protection circuit 430 detects the voltage to monitor the SAT voltage for the drive target switch SW1.

The DESAT protection circuit 430 inputs a monitoring signal Sdst corresponding to the monitored state to the ECU 600. The ECU 600 controls the PWM signal S2 according to the monitoring signal Sdst. When a voltage between the collector and the emitter exceeds a predetermined voltage value, the driver-side logic circuit 401y turns off the drive target switch SW10 based on the PWM signal S2.

### About Soft Turning On

The soft turning on refers to turning on the drive target switch SW10 while increasing the gate voltage of the drive target switch SW10 with a predetermined slew rate. As compared with a normal turn-on operation, the soft turn-on operation takes a long time until the gate voltage of the drive target switch SW10 exceeds a threshold voltage. After the gate voltage of the drive target switch SW10 exceeds the threshold voltage, the on-resistance of the drive target switch SW10 is gradually lowered as the soft turn-on voltage Vs is increased.

Incidentally, a capacitor for smoothing a direct-current voltage may be connected to the node n1 or the node n2 (not shown). In a protection operation or the like, it is necessary to gradually draw out charge from the smoothing capacitor. Here, the drive target switch SW10 is soft turned on. As described above, the on-resistance of the drive target switch SW10 is gradually lowered by the soft turn-on operation. Hence, it is possible to gradually draw out charge from the smoothing capacitor.

### About Active Short-Circuit Function

The electronic device 400 has the active short-circuit function. The signal transmission device 200Y corresponds to the active short-circuit function. The active short-circuit function refers to the function of forcibly performing, with the driver chip 400y, control on the gate voltage of the drive target switch SW10 without arbitrarily depending on the controller chip 350y (hence, the ECU 600).

When the driver chip 400y does not perform the active short-circuit function (in a normal state), the procedure is as follows. In this case, the low-level ASC signal S1y is input from the drive-side ASC controller 700y to the driver-side logic circuit 401y via the external terminal T3.

When the ASC signal S1y is low, as described above, the driver-side logic circuit 401y generates the high-side signal GH and the low-side signal GL based on the PWM signal S2.

On the other hand, when the driver chip 400y performs the active short-circuit function, the procedure is as follows. In this case, the high-level ASC signal S1y is input from the drive-side ASC controller 700y to the driver-side logic circuit 401y via the external terminal T3.

When the ASC signal S1y is high, the driver-side logic circuit 401y ignores the PWM signal S2 and performs the active short-circuit function. A specific description will be given below.

When the driver-side logic circuit 401y receives an input of the high-level ASC signal S1y, the driver-side logic circuit 401y ignores the PWM signal S2, and brings the drive target switch SW10 into an arbitrary state. The arbitrary state refers to one of a state where the drive target switch SW10 is on, a state where the drive target switch SW10 is off and the gate open state of the drive target switch SW10. A specific description will be given below.

When the driver-side logic circuit 401y receives an input of the high-level ASC signal S1y, the driver-side logic circuit 401y causes the high-side signal GH and the low-side signal GL to have arbitrary voltage values without depending on the PWM signal S2. Here, the target values of the voltage values of the high-side signal GH and the low-side signal GL are stored in the nonvolatile memory 403. A plurality of values corresponding to the arbitrary states described above are stored in the nonvolatile memory 403 as the target values.

Hence, when the driver-side logic circuit 401y receives an input of the high-level ASC signal S1y, the driver-side logic circuit 401y reads the target values from the nonvolatile memory 403 via the register 402. Then, the driver-side logic circuit 401y sets the voltage values of the high-side signal GH and the low-side signal GL to the target values.

Incidentally, as described above, the soft turn-on operation takes a relatively long time until the drive voltage Vge exceeds the threshold voltage of the drive target switch SW10. Then, the DESAT protection circuit 430 may perform an erroneous operation on the drive target switch SW10. A specific description will be given below.

As described above, the soft turn-on operation takes a relatively long time until the drive voltage Vge exceeds the threshold voltage of the drive target switch SW10. Then, the DESAT protection circuit 430 may start monitoring the SAT voltage of the drive target switch SW10 in a state where the drive voltage Vge does not exceed the threshold voltage of the drive target switch SW10 (=in a state where the drive target switch SW10 is off). Specifically, in the state where the drive target switch SW10 is off, the DESAT protection circuit 430 attempts to cause a current to flow between the collector and the emitter of the drive target switch SW10.

However, an area between the collector and the emitter of the drive target switch SW10 is in a non-conductive state, and thus no current flows. Then, the capacitor C3 is unintentionally charged. Hence, a voltage at the external terminal T9 is increased regardless of the SAT voltage of the drive target switch SW10.

Thus, the DESAT protection circuit 430 may erroneously detect that an overvoltage occurs between the collector and the emitter of the drive target switch SW10. When the erroneous detection is made, the drive target switch SW10 is forcibly turned off regardless of a situation in which it is originally intended to soft turn on the drive target switch SW10.

Here, in the active short-circuit function described above, the PWM signal S2 is ignored, and the drive target switch SW10 can be brought into the arbitrary state. For example, the active short-circuit function brings the drive target switch SW10 into the gate open state. In this case, even if the DESAT protection circuit 430 makes the erroneous detection, the driver-side logic circuit 401y ignores the PWM signal S2 and can forcibly bring the drive target switch SW10 into the gate open state.

In this state, the driver-side logic circuit 401y turns on the switch SW5. In this way, even if the DESAT protection circuit 430 makes the erroneous detection, the drive target switch SW10 can be forcibly soft turned on.

### Considerations on Omission of Nonvolatile Memory

Incidentally, in recent years, for reasons such as a reduction in circuit area, a reduction in manufacturing costs and the lie, there has been a demand for omitting a controller-side nonvolatile memory (corresponding to the nonvolatile memory 353 described above) and a driver-side nonvolatile memory (corresponding to the nonvolatile memory 403 described above).

If the nonvolatile memory 353 and the nonvolatile memory 403 are omitted, when the signal transmission device 200Y is started up, information on various settings related to the active short-circuit function (=the target values and the like of the high-side signal GH and the low-side signal GL for bringing the drive target switch SW10 into the arbitrary state described above) needs to be temporarily stored in the register 402 from the ECU 600 via the input signal IN2, the control signal S3, the control signal S4, the data signal Sd and the control signal S5.

Here, it is assumed that a communication trouble occurs in a path from the ECU 600 to the register 402. Then, when the signal transmission device 200Y is started up, the information on various settings related to the active short-circuit function cannot be temporarily stored in the register 402. Then, as described above, the active short-circuit function is not effectively performed.

Hence, even if drive control can be performed on the drive target switch SW10 using the PWM signal S2, when the DESAT protection circuit 430 makes the erroneous detection, it is impossible to bring the drive target switch SW10 into the gate open state. Then, the drive target switch SW10 cannot be soft turned on. Therefore, it is impossible to draw out charge from the smoothing capacitor.

In order to cope with such a problem, the signal transmission device 200X in the present disclosure can suppress, while reducing the circuit area, the occurrence of a problem in which the active short-circuit function is not effectively performed. The signal transmission device 200X according to the embodiment of the present disclosure will be described in detail below. The signal transmission device 200X according to the embodiment of the present disclosure incudes configurations common to the signal transmission device 200Y described previously. Hence, the common configurations are identified with the same symbols, and description thereof is omitted.

### About Signal Transmission Device 200X According to the Embodiment of the Present Disclosure

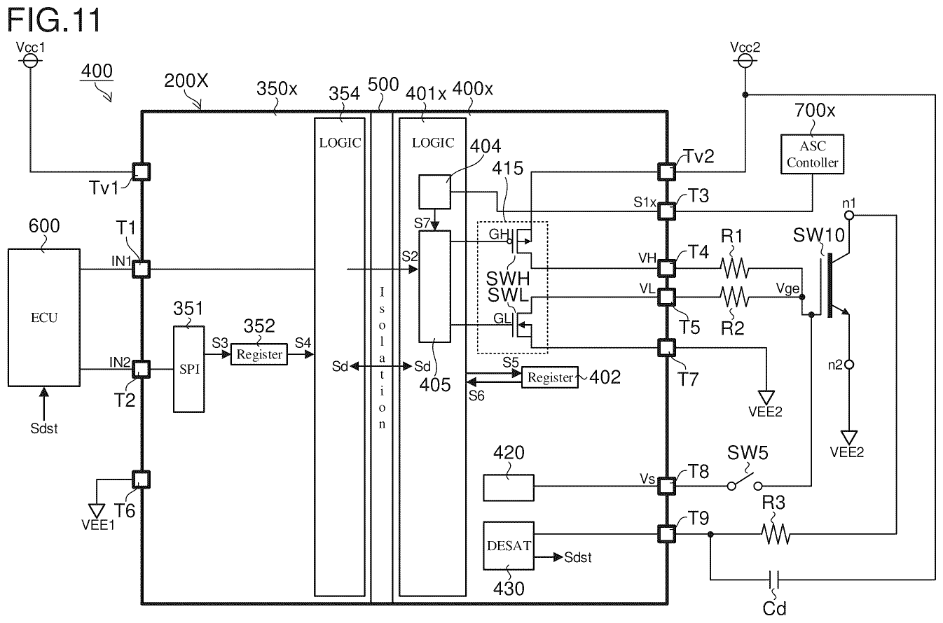

FIG. 11 is a diagram showing the configuration of the signal transmission device X in the present disclosure. As shown in FIG. 11, the signal transmission device 200X can be incorporated in the electronic device 400 as with the signal transmission device 200Y described previously. The drive-side ASC controller 700x of the present configuration example is partially different from the drive-side ASC controller 700y described previously. The drive-side ASC controller 700x will first be described.

The drive-side ASC controller 700x inputs an ASC signal S1x to the external terminal T3. The ASC signal S1x is a signal which is switched between a high level (second logic level) and a low level (first logic level). When the active short-circuit function is performed, the drive-side ASC controller 700x switches the ASC signal S1x high.

The drive-side ASC controller 700x can arbitrarily change the voltage value of the high-level ASC signal S1x to a plurality of setting values which are set in a plurality of stages. Specifically, the drive-side ASC controller 700x uses the active short-circuit function to change the voltage value of the high-level ASC signal S1x according to the state of the drive target switch SW10 which is the target.

For example, when the active short-circuit function is used to bring the drive target switch SW10 into an off state, the voltage value of the ASC signal S1x is set to a first setting value. The first setting value is higher than a first threshold voltage Vth1 which will be described later and is lower than a second threshold voltage Vth2 which will be described later.

For example, when the active short-circuit function is used to bring the drive target switch SW10 into the gate open state, the drive-side ASC controller 700x sets the ASC signal S1x to a second setting value. The second setting value is higher than the second threshold voltage Vth2 and is lower than a third threshold voltage Vth3 which will be described later.

For example, when the active short-circuit function is used to bring the drive target switch SW10 into an on state, the drive-side ASC controller 700x sets the ASC signal S1x to a third setting value. The third setting value is higher than the third threshold voltage Vth3.

During the normal operation (when the active short-circuit function is not performed), the drive-side ASC controller 700x sets the voltage value of the ASC signal S1x to a fourth setting value (=a low level). The fourth setting value is lower than the first threshold voltage Vth1. The details of the first threshold voltage Vth1 to the third threshold voltage Vth3 will be described later.

The signal transmission device 200X will then be described. The signal transmission device 200X is a gate driver circuit which drives and controls the drive target switch SW10. The signal transmission device 200X receives an input of the input signal IN1 from the ECU 600 to generate the drive voltage Vge. The signal transmission device 200X corresponds to the signal transmission device 200 described previously.

The signal transmission device 200X is configured to transmit, while insulating the area between the primary circuit system (VCC1-VEE1) and the secondary circuit system (VCC2-VEE2), the gate drive signal from the primary circuit system to the secondary circuit system.

The signal transmission device 200X includes terminals (in the figure, external terminals T1 to T9 equivalent to those described previously, the primary-side power supply terminal Tv1 and the secondary-side power supply terminal Tv2) as means for communicating with the outside.

The signal transmission device 200X controls voltages generated at the external terminal T4 and the external terminal T5 to change the drive voltage Vge, and thereby drives and controls the drive target switch SW10. The internal configuration of the signal transmission device 200X will be described below.

The signal transmission device 200X includes a transformer chip 500 equivalent to that described previously. The signal transmission device 200X includes, in addition to the transformer chip 500, a controller chip 350x and a driver chip 400x. The signal transmission device 200X seals the controller chip 350x, the driver chip 400x and the transformer chip 500 into one package.

The controller chip 350x corresponds to the primary circuit system 200p described previously. The controller chip 350x includes an SPI controller 351, a register 352 and a controller-side logic circuit 354 equivalent to those described previously.

The transformer chip 500 establishes transmission and reception of signals between the controller chip 350x and the driver chip 400x while insulating an area between the controller chip 350x and the driver chip 400x based on a direct current.

The primary windings of the transformer chip 500 are connected to the controller chip 350x. The secondary windings of the transformer chip 500 are connected to the driver chip 400x. The PWM signal S2 input to the primary windings of the transformer chip 500 is transmitted to the secondary windings and is input to the driver chip 400x.

The driver chip 400x corresponds to the secondary circuit system 200s described previously. A driver for drive control of the drive target switch SW10 is integrated into the driver chip 400x.

The driver chip 400x is driven by receiving the supply of the secondary-side power supply voltage VCC2 via the secondary-side power supply terminal Tv2. The driver chip 400x controls the drive voltage Vge based on the input PWM signal S2. A specific description will be given below.

The driver chip 400x includes an output stage 415, a register 402, a soft turn-on circuit 420 and a DESAT protection circuit 430 equivalent to those described previously. In addition, the driver chip 400x includes a driver-side logic circuit 401x.

The driver-side logic circuit 401x receives an input of the PWM signal S2. The driver-side logic circuit 401x generates the high-side signal GH and the low-side signal GL corresponding to the PWM signal S2.

The driver-side logic circuit 401x receives an input of the data signal Sd to generate the control signal S5 and inputs the control signal S5 to the register 402. The control signal S5 includes predetermined information (such as the information described above) included in the data signal Sd. The register 402 receives an input of the control signal S5, and stores the information included in the control signal S5 therein in a volatile manner.

The register 402 can generate, according to the control signal S5, the control signal S6 such that the control signal S6 includes the information stored therein. In this case, the register 402 inputs the control signal S6 to the driver-side logic circuit 401x at an arbitrary timing.

The gate of the high-side switch SWH receives an input of the high-side signal GH from the driver-side logic circuit 401x. The gate of the low-side switch SWL receives an input of the low-side signal GL from the driver-side logic circuit 401x.

For example, when the drive target switch SW10 is turned on (when the drive voltage Vge is switched high), the driver-side logic circuit 401x turns on the high-side switch SWH and turns off the low-side switch SWL. In other words, the driver-side logic circuit 401x switches the high-side signal GH and the low-side signal GL low. In this way, the secondary-side power supply voltage VCC2 is supplied to the external terminal T4, and thus the drive voltage Vge is switched high. Then, the drive target switch SW10 is turned on.

For example, when the drive target switch SW10 is turned off (when the drive voltage Vge is switched low), the driver-side logic circuit 401x turns off the high-side switch SWH and turns on the low-side switch SWL. In other words, the driver-side logic circuit 401x switches the high-side signal GH and the low-side signal GL high. In this way, the reference voltage VEE2 is supplied to the external terminal T5, and thus the drive voltage Vge is switched low. Then, the drive target switch SW10 is turned off.

For example, when the drive target switch SW10 is brought into the gate open state, the driver-side logic circuit 401x turns off the high-side switch SWH and the low-side switch SWL. In other words, the high-side signal GH is switched high, and the low-side signal GL is switched low. Then, the gate of the drive target switch SW10 is brought into the floating state (=high impedance state). In this way, the drive target switch SW10 is brought into the gate open state.

During the normal operation, the driver-side logic circuit 401x receives an input of the PWM signal S2 to generate the high-side signal GH and the low-side signal GL. On the other hand, when the active short-circuit function is performed, the driver-side logic circuit 401x ignores the PWM signal S2 and generates the high-side signal GH and the low-side signal GL based on the ASC signal S1x. A configuration related to the active short-circuit function in the present disclosure will be described in detail below.

### About Configuration Related to active Short-Circuit Function

The signal transmission device 200X corresponds to the active short-circuit function. A specific description will be given below. The driver-side logic circuit 401x receives an input of the ASC signal S1x from the drive-side ASC controller 700x via the external terminal T3.

When the ASC signal S1x is low (=when the voltage value of the ASC signal S1x is the fourth setting value), the driver-side logic circuit 401x generates the high-side signal GH and the low-side signal GL based on the PWM signal S2 as described above.

On the other hand, when the ASC signal S1x is high, the driver-side logic circuit 401x ignores the PWM signal S2, and generates the high-side signal GH and the low-side signal GL based on the ASC signal S1x.

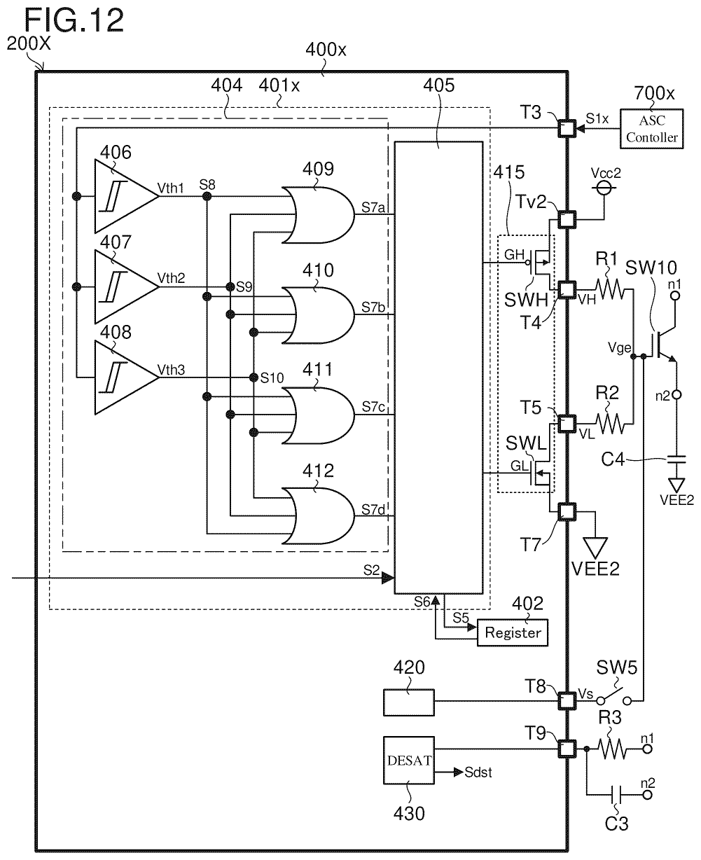

The configuration related to the active short-circuit function of the driver-side logic circuit 401x will be described in detail. FIG. 12 is a diagram showing the configuration of the driver-side logic circuit 401x. As shown in FIG. 12, the driver-side logic circuit 401x includes an ASC signal determination circuit 404 and a drive control circuit 405.

Here, as described above, the drive-side ASC controller 700x sets the voltage value of the ASC signal S1x to one of the first to fourth setting values. The ASC signal determination circuit 404 determines whether the voltage value of the ASC signal S1x exceeds each of a plurality of threshold voltages (the first threshold voltage Vth1 to the third threshold voltage Vth3). In this way, which one of the first to fourth setting values the voltage value of the ASC signal S1x is is determined.

The ASC signal determination circuit 404 generates a determination result signal S7 corresponding to the result of the determination and inputs the determination result signal S7 to the drive control circuit 405. The drive control circuit 405 performs the active short-circuit function according to the determination result signal S7 or does not perform the active short-circuit function but performs the normal operation. A specific description will be given below.

When the active short-circuit function is performed, the drive control circuit 405 ignores the PWM signal S2, and generates the high-side signal GH and the low-side signal GL based on the determination result signal S7. When the active short-circuit function is not performed (=in the normal operation), the drive control circuit 405 generates the high-side signal GH and the low-side signal GL based on the PWM signal S2.

The configuration of the ASC signal determination circuit 404 will be described in more detail. The ASC signal determination circuit 404 includes logic circuits 406 to 408, an OR gate 409 and NOR gates 410 to 412.

Each of the logic circuits 406 to 408 is a logic circuit which changes its output voltage according to whether an input voltage exceeds a predetermined threshold voltage. For example, each of the logic circuits 406 to 408 can be a Schmitt trigger circuit. The input end of each of the logic circuits 406 to 408 is connected to the external terminal T3. The output end of each of the logic circuits 406 to 408 is input to the input end of each of the OR gate 409 and the NOR gates 410 to 412.

The logic circuit 406 receives an input of the ASC signal S1x to determine whether the ASC signal S1x exceeds the first threshold voltage Vth1. The logic circuit 406 generates an output signal S8 corresponding to the result of the determination. Specifically, when the ASC signal S1x exceeds the first threshold voltage Vth1, the logic circuit 406 switches the output signal S8 high. By contrast, when the ASC signal S1x falls below the first threshold voltage Vth1, the logic circuit 406 switches the output signal S8 low.

The logic circuit 407 receives an input of the ASC signal S1x to determine whether the ASC signal S1x exceeds the second threshold voltage Vth2. The logic circuit 407 generates an output signal S9 corresponding to the result of the determination. Specifically, when the ASC signal S1x exceeds the second threshold voltage Vth2, the logic circuit 407 switches the output signal S9 high. By contrast, when the ASC signal S1x falls below the second threshold voltage Vth2, the logic circuit 407 switches the output signal S9 low.

The logic circuit 408 receives an input of the ASC signal S1x to determine whether the ASC signal S1x exceeds the third threshold voltage Vth3. The logic circuit 408 generates an output signal S10 corresponding to the result of the determination. Specifically, when the ASC signal S1x exceeds the third threshold voltage Vth3, the logic circuit 408 switches the output signal S10 high. By contrast, when the ASC signal S1x falls below the third threshold voltage Vth3, the logic circuit 408 switches the output signal S10 low.

As shown in FIG. 12, the OR gate 409 receives inputs of the output signals S8 to S10 to generate a determination result signal S7a. The NOR gate 410 receives an inverting input of the output signal S8 and inputs of the output signals S9 and S10 to generate a determination result signal S7b. The NOR gate 411 receives inverting inputs of the output signals S8 and S9 and an input of the output signal S10 to generate a determination result signal S7c. The NOR gate 412 receives inverting inputs of the output signals S8 to S10 to generate a determination result signal S7d. The determination result signals S7a to S7d may be interpreted to be included in the determination result signal S7 described above.

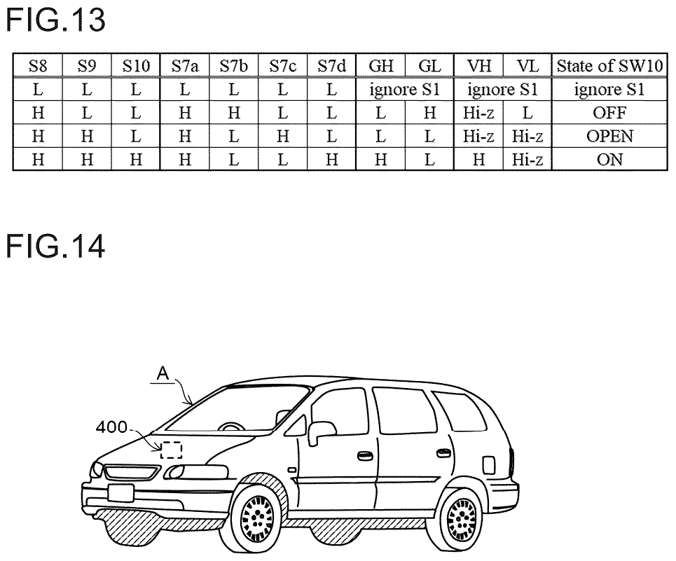

FIG. 13 is a table showing a correlation between the logic levels of the output signals S8 to S10, the determination result signals S7a to S7d, the high-side signal GH, the low-side signal GL, a terminal voltage VH and a terminal voltage VL and the state of the drive target switch SW10. In FIG. 13, a high level is represented by “H”, a low level is represented by “L”and a high impedance state is represented by “Hi-Z”.

As shown in FIG. 13, when at least one of the output signals S8 to S10 are high, the OR gate 409 switches the determination result signal S7a high. By contrast, when all the output signals S8 to S10 are low, the OR gate 409 switches the determination result signal S7a low.

Only when all three input voltages which are input to each of the NOR gates 410 to 412 are low, each of the NOR gates 410 to 412 switches the output signal (one of the determination result signals S7a to S7d) high. Otherwise, each of the NOR gates 410 to 412 switches the output signal low.

Only when the inverting input value of the output signal S8 is low (=the output signal S8 is high), and the output signals S8 and S10 are low, the NOR gate 410 switches the determination result signal S7b high. Otherwise, the NOR gate 410 switches the determination result signal S7b low.

Only when the inverting input values of the output signals S8 and S9 are low (=the output signals S8 and S9 are high), and the output signal S10 is low, the NOR gate 411 switches the determination result signal S7c high. Otherwise, the NOR gate 411 switches the determination result signal S7c low.

Only when all the inverting input values of the output signals S8 to S10 are low (=all the output signals S8 to S10 are high), the NOR gate 412 switches the determination result signal S7d high. Otherwise, the NOR gate 412 switches the determination result signal S7d low.

The drive control circuit 405 receives inputs of the determination result signals S7a to S7d and the PWM signal S2 to generate the high-side signal GH and the low-side signal GL. A specific description will be given below.

The determination result signal S7a is said to be a flag for interrupt processing. In other words, when the determination result signal S7a is raised high, the control of the performance of the active short-circuit function is interrupted by the drive control of the drive target switch SW10 performed by the PWM signal S2.

When the determination result signal S7a is low, the drive control circuit 405 normally generates the high-side signal GH and the low-side signal GL based on the PWM signal S2. Here, the drive target switch SW10 is driven according to the PWM signal S2.

On the other hand, when the determination result signal S7a is high, the drive control circuit 405 ignores the PWM signal S2, and generates the high-side signal GH and the low-side signal GL corresponding to the determination result signals S7b to S7d. Here, the drive target switch SW10 is driven and controlled according to the voltage value of the ASC signal S1x.

The drive control of the drive target switch SW10 performed by the ASC signal S1x will be described in detail. As shown in FIG. 13, when the determination result signals S7a and S7b are high, and the determination result signals S7c and S7d are low, the high-side signal GH is turned low, and the low-side signal GL is turned high. Hence, the high-side switch SWH is turned off, and the low-side switch SWL is turned on. In this way, the terminal voltage VH is brought into a high impedance state, and the terminal voltage VL is switched low. Here, the drive voltage Vge is switched low, and thus the drive target switch SW10 is turned off.

When the determination result signals S7a and S7c are high, and the determination result signals S7b and S7d are low, the high-side signal GH and the low-side signal GL are switched low. Hence, the high-side switch SWH and the low-side switch SWL are turned off. In this way, the terminal voltage VH and the terminal voltage VL are brought into a high impedance state. Then, here, the drive target switch SW10 is brought into the gate open state (in FIG. 13, into an “open”state).

When the determination result signals S7a and S7d are high, and the determination result signals S7b and S7c are low, the high-side signal GH is switched high, and the low-side signal GL is switched low. Hence, the high-side switch SWH is turned on, and the low-side switch SWL is turned on. In this way, the terminal voltage VH is switched high, and the terminal voltage VL is brought into a high impedance state. Then, here, the drive voltage Vge is switched high, and the drive target switch SW10 is turned on.

As described above, in the signal transmission device 200X in the present disclosure, even when the nonvolatile memory (corresponding to the nonvolatile memory 403) is omitted from the driver chip 400x, the active short-circuit function can be performed by the processing on the side of the driver chip 400x. Hence, when the signal transmission device 200X is started up, information necessary for the active short-circuit function does not need to be transmitted from the ECU 600 to the register 402. In this way, even if a communication failure can occur in a signal path from the ECU 600 to the register 402, the active short-circuit function can be effectively performed.

The nonvolatile memories (corresponding to the nonvolatile memories 353 and 403) can be omitted from the controller chip 350x and the driver chip 400x. Hence, the circuit area of the signal transmission device 200X can be reduced.

The drive target switch SW10 is forcibly brought into the gate open state using the active short-circuit function, then the switch SW5 is turned on and thus it is possible to soft turn on the drive target switch SW10. In this way, even if a communication failure can occur as described above, it is possible to draw out charge from the smoothing capacitor (not shown) connected to the node n1.

Furthermore, even if the erroneous detection made by the DESAT protection circuit 430 occurs as described above, the driver chip 400x (more specifically, the drive control circuit 405) ignores the PWM signal S2, and can forcibly bring the drive target switch SW10 into the gate open state on the side of the driver chip 400x.

As described above, when the signal transmission device 200X is started up, the information necessary for the active short-circuit function does not need to be transmitted from the ECU 600 to the register 402. Hence, signal processing and various types of control when the signal transmission device 200X is started up can be relatively simplified.

As described above, the logic circuits 406 to 408 can be Schmitt buffers. In this way, the logic circuits 406 to 408 output the output signals S8 to S10 in a state where hysteresis is provided in inputs. Even if noise occurs in the ASC signal S1x or the ASC signal S1x is instantaneously increased due to a failure, it is possible to suppress the occurrence of a problem in which the logic circuits 406 to 408 erroneously detect the ASC signal S1x. In this way, the active short-circuit function can be performed accurately.

FIG. 14 is a diagram showing the configuration of the vehicle A which incorporates the electronic device 400. As shown in FIG. 14, the electronic device 400 in the present disclosure can be suitably utilized in a power supply device, a motor driving device or the like in a vehicle-mounted device incorporated in the vehicle A. Examples of the vehicle A include an engine vehicle and an electric vehicle FCEV/FCV.

### Variations

The present disclosure is not limited to the embodiment described above, and various changes can be made without departing from the spirit of the present disclosure. For example, although the drive target switch SW10 is an IGBT, the present disclosure is not limited to this configuration. For example, the drive target switch SW10 can be an N-channel or P-channel MOSFET. In this case, the emitter and the collector of the drive target switch SW10 are replaced with the source and the drain, and thus the meanings of the present specification, FIG. 1 to FIG. 14 and the scope of claims can be interpreted. The SAT voltage here is interpreted to be a voltage between the gate and source during the on period of the drive target switch SW10.

For example, the soft turn-on circuit 420 can be used, instead of the soft turn-on voltage Vs, a soft turn-off voltage Vs which is gradually lowered with a predetermined slew rate. In this case, the soft turn-off voltage Vs is supplied to the gate of the drive target switch SW10, and thus it is possible to soft turn off the drive target switch SW10.

For example, an output end of a predetermined signal can be connected to the gate of the drive target switch SW10. In this way, the active short-circuit function is used to forcibly bring the drive target switch SW10 into an open state, and then the drive control of the drive target switch SW10 can be performed using the predetermined signal.

### Additional Notes

A signal transmission device (200X) disclosed in the specification includes: a transmission circuit (350x) configured to output, according to an input signal (IN1, IN2), a control signal (S2) that is pulse-driven; a reception circuit (400x) configured to drive a drive target switch (SW10) according to the control signal (S2); and an insulating circuit (500) configured to transmit the control signal (S2) while insulating an area between the transmission circuit (350x) and the reception circuit (400x), the reception circuit (400x) receives an input of an external signal (S1x) different from the input signal (IN1, IN2) and the reception circuit (400x) drives the drive target switch (SW10) based on the control signal (S2) in a state where the external signal (S1x) is at a first logic level at which a voltage of the external signal (S1x) is equal to or lower than a first threshold voltage (Vth1), and drives and controls the drive target switch (SW10) based on the external signal (S1x) regardless of the control signal (S2) in a state where the external signal (S1x) is at a second logic level at which the voltage of the external signal (S1x) is higher than the first threshold voltage (first configuration).

In the signal transmission device (200X) according to the first configuration, when the external signal (S1x) is at the second logic level, the reception circuit (400x) brings the drive target switch (SW10) into one of an on state, an off state and a gate open state (second configuration).

In the signal transmission device (200X) according to the first or second configuration, the reception circuit (400x) includes: an output stage (415) configured to drive the drive target switch (SW10); and a logic circuit (401x) configured to control, when the external signal (S1x) is at the first logic level, the output stage (415) such that the output stage (415) drives the drive target switch (SW10) based on the input signal (IN1, IN2) and to control, when the external signal (S1x) is at the second logic level, the output stage (415) such that the output stage (415) drives the drive target switch (SW10) based on the external signal (S1x) regardless of the input signal (IN1, IN2) (third configuration).

In the signal transmission device (200X) according to the third configuration, the output stage (415) includes: a high-side switch (SWH) that supplies, in an on state, a first voltage exceeding an on-threshold voltage of the drive target switch (SW10) to a control end of the drive target switch (SW10); and a low-side switch (SWL) that supplies, in an on state, a second voltage less than the on-threshold voltage to the control end, the logic circuit (401x) includes: an external signal determination circuit (404) configured to be capable of determining a logic level of the external signal (S1x); and a drive control circuit (405) configured to control drive of the high-side switch (SWH) and the low-side switch (SWL) based on a result of the determination performed by the external signal determination circuit (404) and the input signal (IN1, IN2), when the external signal (S1x) is at the first logic level, based on the input signal (IN1, IN2), the drive control circuit (405) controls the drive such that the high-side switch (SWH) is turned on and the low-side switch (SWL) is turned off or controls the drive such that the high-side switch (SWH) is turned off and the low-side switch (SWL) is turned on and when the external signal (S1x) is at the second logic level, based on the external signal (S1x), regardless of the input signal (IN1, IN2), the drive control circuit controls the drive such that the high-side switch (SWH) is turned on and the low-side switch (SWL) is turned off, controls the drive such that the high-side switch (SWH) is turned off and the low-side switch (SWL) is turned on or controls the drive such that the high-side switch (SWH) is turned off and the low-side switch (SWL) is turned off (fourth configuration).

In the signal transmission device (200X) according to the fourth configuration, the external signal determination circuit (404) is capable of determining whether a voltage value of the external signal (S1x) exceeds each of a plurality of threshold voltages (Vth1 to Vth3) including the first threshold voltage (Vth1) (fifth configuration).

In the signal transmission device (200X) according to the fifth configuration, the threshold voltages (Vth1 to Vth3) include: the first threshold voltage (Vth1); a second threshold voltage (Vth2) that is higher than the first threshold voltage (Vth1); and a third threshold voltage (Vth3) that is higher than the second threshold voltage (Vth2), and the drive control circuit (405) drives and controls the high-side switch (SWH) and the low-side switch (SWL) based on the input signal (IN1, IN2) when the external signal determination circuit (404) determines that the voltage value of the external signal (S1x) is lower than the first threshold voltage (Vth1), drives and controls the high-side switch (SWH) and the low-side switch (SWL) regardless of the input signal (IN1, IN2) such that the drive target switch (SW10) is brought into a first state which is one of the on state, the off state and the gate open state when the external signal determination circuit (404) determines that the voltage value of the external signal (S1x) is higher than the first threshold voltage (Vth1) and lower than the second threshold voltage (Vth2), drives and controls the high-side switch (SWH) and the low-side switch (SWL) regardless of the input signal (IN1, IN2) such that the drive target switch (SW10) is brought into a second state, other than the first state, which is one of the on state, the off state and the gate open state when the external signal determination circuit (404) determines that the voltage value of the external signal (S1x) is higher than the second threshold voltage (Vth2) and lower than the third threshold voltage (Vth3) and drives and controls the high-side switch (SWH) and the low-side switch (SWL) regardless of the input signal (IN1, IN2) such that the drive target switch (SW10) is brought into a third state, other than the first state and the second state, which is one of the on state, the off state and the gate open state when the external signal determination circuit (404) determines that the voltage value of the external signal (S1x) is higher than the second threshold voltage (Vth2) and lower than the third threshold voltage (Vth3) (sixth configuration).

An electronic device (400) disclosed in the specification includes: the signal transmission device (200X) according to any one of the first to sixth configurations; a control circuit (600) configured to generate the input signal (IN1, IN2); an external signal generation circuit (700x) configured to generate the external signal (S1x); and the drive target switch (seventh configuration).

The electronic device (400) according to the seventh configuration further includes: a protection circuit (430) configured to monitor an SAT voltage for the drive target switch (SW10), and the external signal generation circuit (700x) sets the external signal (S1x) to the first logic level or the second logic level according to a result of the monitoring performed by the protection circuit (430) (eighth configuration).

A vehicle (A) disclosed in the specification includes: the electronic device (400) according to the seventh or eighth configuration (ninth configuration).

1. A signal transmission device comprising:
a transmission circuit configured to output, according to an input signal, a control signal that is pulse-driven;
a reception circuit configured to drive a drive target switch according to the control signal; and
an insulating circuit configured to transmit the control signal while insulating an area between the transmission circuit and the reception circuit,
wherein the reception circuit receives an input of an external signal different from the input signal, and
the reception circuit
drives the drive target switch based on the control signal in a state where the external signal is at a first logic level at which a voltage of the external signal is equal to or lower than a first threshold voltage, and
drives and controls the drive target switch based on the external signal regardless of the control signal in a state where the external signal is at a second logic level at which the voltage of the external signal is higher than the first threshold voltage.

2. The signal transmission device according to claim 1,
wherein when the external signal is at the second logic level, the reception circuit brings the drive target switch into one of an on state, an off state and a gate open state.

3. The signal transmission device according to claim 1,
wherein the reception circuit includes:
an output stage configured to drive the drive target switch; and
a logic circuit configured to control, when the external signal is at the first logic level, the output stage such that the output stage drives the drive target switch based on the input signal and to control, when the external signal is at the second logic level, the output stage such that the output stage drives the drive target switch based on the external signal regardless of the input signal.

4. The signal transmission device according to claim 3,
wherein the output stage includes:
a high-side switch that supplies, in an on state, a first voltage exceeding an on-threshold voltage of the drive target switch to a control end of the drive target switch; and
a low-side switch that supplies, in an on state, a second voltage less than the on-threshold voltage to the control end,
the logic circuit includes:
an external signal determination circuit configured to be capable of determining a logic level of the external signal; and
a drive control circuit configured to control drive of the high-side switch and the low-side switch based on a result of the determination performed by the external signal determination circuit and the input signal,
when the external signal is at the first logic level, based on the input signal, the drive control circuit
controls the drive such that the high-side switch is turned on and the low-side switch is turned off or
controls the drive such that the high-side switch is turned off and the low-side switch is turned on and
when the external signal is at the second logic level, based on the external signal, regardless of the input signal, the drive control circuit
controls the drive such that the high-side switch is turned on and the low-side switch is turned off,
controls the drive such that the high-side switch is turned off and the low-side switch is turned on or
controls the drive such that the high-side switch is turned off and the low-side switch is turned off.

5. The signal transmission device according to claim 4,
wherein the external signal determination circuit is capable of determining whether a voltage value of the external signal exceeds each of a plurality of threshold voltages including the first threshold voltage.

6. The signal transmission device according to claim 5,
wherein the threshold voltages include:
the first threshold voltage;
a second threshold voltage that is higher than the first threshold voltage; and
a third threshold voltage that is higher than the second threshold voltage, and
the drive control circuit
drives and controls the high-side switch and the low-side switch based on the input signal when the external signal determination circuit determines that the voltage value of the external signal is lower than the first threshold voltage,
drives and controls the high-side switch and the low-side switch regardless of the input signal such that the drive target switch is brought into a first state which is one of the on state, the off state and the gate open state when the external signal determination circuit determines that the voltage value of the external signal is higher than the first threshold voltage and lower than the second threshold voltage,
drives and controls the high-side switch and the low-side switch regardless of the input signal such that the drive target switch is brought into a second state, other than the first state, which is one of the on state, the off state and the gate open state when the external signal determination circuit determines that the voltage value of the external signal is higher than the second threshold voltage and lower than the third threshold voltage and
drives and controls the high-side switch and the low-side switch regardless of the input signal such that the drive target switch is brought into a third state, other than the first state and the second state, which is one of the on state, the off state and the gate open state when the external signal determination circuit determines that the voltage value of the external signal is higher than the second threshold voltage and lower than the third threshold voltage.

7. An electronic device comprising:
the signal transmission device according to claim 1;
a control circuit configured to generate the input signal;
an external signal generation circuit configured to generate the external signal; and
the drive target switch.

8. The electronic device according to claim 7 further comprising:
a protection circuit configured to monitor an SAT voltage for the drive target switch,
wherein the external signal generation circuit sets the external signal to the first logic level or the second logic level according to a result of the monitoring performed by the protection circuit.

9. A vehicle comprising:
the electronic device according to claim 7.
